(19) United States
(12) Patent Application Publication
(10) Pub. No.: US 2022/0244104 A1
(43) Pub. Date: Aug. 4, 2022

(54) SPECTRAL SENSOR MODULE

(71) Applicant: Spectricity, Mechelen (BE)

(72) Inventors: Jakub Raczkowski, Bertem (BE); Ward van der Tempel, Keerbergen (BE); Ruben Lieten, Heverlee (BE); Jonathan Borremans, Lier (BE); Maarten De Bock, Gent (BE); Peter van Wesemael, Antwerpen (BE)

(73) Assignee: Spectricity, Mechelen (BE)

(21) Appl. No.: 17/646,386

(22) Filed: Dec. 29, 2021

Related U.S. Application Data
(60) Provisional application No. 63/143,546, filed on Jan. 29, 2021.

(51) Int. Cl. G01J 3/51; H01L 27/146

(52) U.S. Cl. CPC G01J 3/51; H01L 27/14618; H01L 27/14685; H01L 27/14643; H01L 27/14625; H01L 27/1462

(57) ABSTRACT

A sensor system provides a plurality of sets of optical sensors configured in a layer and a plurality of sets of optical filters configured in a layer, where the bottom surface of the plurality of sets of optical filters is located proximal to the top surface of the plurality of sets of optical sensors and where a set of optical filters of the plurality of sets of optical filters includes a plurality of optical filters that are arranged in a pattern so that at least some optical filters of the plurality of optical filters are configured to pass light in a different wavelength range. The sensor system provides one or more rejection filters configured as a layer and a first set of optical elements, where the one or more rejection filters and the first set of optical elements are configured in a stack that is located above the top layer of the plurality of sets of optical filters. The sensor system includes one or more processing modules configured to receive an output from each optical sensor of the plurality of sets of optical sensors and generate a spectral response based on the output.

### RELATED APPLICATIONS

The present U.S. Utility patent application claims priority pursuant to 35 USC § 119(e) to U.S. Provisional Application No. 63/143,546, entitled “SPECTRAL SENSOR MODULE”, filed Jan. 29, 2021, which is hereby incorporated herein by reference in its entirety and made part of the present U.S. Utility patent application for all purposes.

### BACKGROUND OF THE INVENTION

### Technical Field of the Invention

This invention relates generally to spectrophotometric sensing and more particularly to spectral sensor modules.

Spectral sensors are used to acquire spectral information of an object or scene. Using spectral sensing, incident light from an object or scene is captured and spectral information is extracted. The spectral sensing may capture spectral information from the object, such as from a single point or from a region of the object or scene. Spatial information can also be acquired, such that the spectral information can also be spatially resolved. In spectral sensing, incident light relating to a spectrum of wavelengths is detected. The spectral sensing may for instance be used in analysis of objects, such as for determination whether a substance having a specific spectral profile is present in the object.

The terms multi-spectral sensing and hyperspectral sensing are used to classify spectral sensing. These terms do not have established definitions, but typically multi-spectral sensing refers to spectral sensing using a plurality of discrete wavelength bands, whereas hyperspectral sensing refers to sensing narrow spectral wavelength bands over a continuous spectral range.

Spectral sensing may be performed by dedicated devices for acquiring spectral content referred to as spectrophotometers (spectrometers). Spectrometers and the individual elements that make up spectrometers can assume a variety of form factors, depending on the application the spectrometer is designed for, along with associated technical elements.

### BRIEF DESCRIPTION OF THE SEVERAL VIEWS OF THE DRAWING(S)

FIG. 1 provides a side cross-sectional view of a sensor module in accordance with the present invention;

FIGS. 2A-2D provide side cross-sectional views of example sensor modules in accordance with the present invention;

FIG. 3 illustrates a light sensitive element that includes multiple depletion regions in accordance with the present invention;

FIG. 4 illustrates another light sensitive element that includes multiple depletion regions in accordance with the present invention;

FIG. 5 provides a side cross-sectional view of an integrated filter and sensor array in accordance with the present invention;

FIG. 6 provides an illustration of an example transmission output in the SWIR band.

FIG. 7A provides a side-view of an imaging device for detecting SWIR wavelengths in accordance with the present invention;

FIG. 7B provides a side-view of another imaging device for detecting SWIR wavelengths in accordance with the present invention;

FIG. 7C provides a side-view of an imaging device for detecting both SWIR wavelengths and wavelengths in visible light wavelengths in accordance with the present invention;

FIG. 8A provides an exploded side illustration of interference filters used to provide periodic black pixels on a sensor array in accordance with the present invention;

FIGS. 8B-8E illustrate the process for forming a double Bragg stack mirror in accordance with the present invention;

FIG. 9A provides a side cross-sectional view of an integrated filter and sensor array in accordance with the present invention;

FIG. 9B provides another side cross-sectional view of an integrated filter and sensor array in accordance with the present invention;

FIG. 10 provides an illustration of the spectral response of a Fabry-Perot interference filter showing transmission peaks for different orders of constructive interference in accordance with the present invention;

FIG. 11A illustrates the transmissive spectra of example plasmonic filters in accordance with the present invention in accordance with the present invention;

FIG. 11B illustrates the respective peak transmission wavelengths for the plasmonic filters as a function of the period in nanometers (nm) in accordance with the present invention;

FIG. 11C provides an example side cross-sectional view of an integrated interference filter and plasmonic rejection filter pair in accordance with the present invention;

FIG. 12A provides an example side cross-sectional view of an imaging system incorporating a micro-lens array and a micro-grating array in accordance with the present invention;

FIG. 12B provides a side view of a lens adapted to redirect incident light on an image sensor in accordance with the present invention;

FIG. 12C provides a side view of a microstructure array adapted to redirect incident light on an image sensor in accordance with the present invention;

FIG. 12D provides a side view of a micromirror array adapted to redirect incident light on an image sensor in accordance with the present invention;

FIG. 12E provides a side view of an example imager adapted to provide a curved surface for collecting incident light in accordance with the present invention;

FIG. 12F provides a side view of another example imager adapted to provide a curved surface for collecting incident light in accordance with the present invention;

FIG. 13 is a perspective view of an example convex micro-lens in accordance with the present invention;

FIG. 14 is a perspective view of an example concave micro-lens in accordance with the present invention;

FIG. 15 provides a side cross-sectional view of a sensor module that includes a package incorporating a package aperture in accordance with the present invention;

FIGS. 16A-D illustrate various sidewall profiles for pinole apertures in accordance with the present invention;

FIG. 17 illustrates scattering from a diffuser element in a sensor system in accordance with the present invention;

FIG. 18A illustrates a sensor system utilizing a modified diffuser element in accordance with the present invention;

FIG. 18B illustrates a multi-layer diffuser element in accordance with the present invention;

FIG. 19A provides a side cross-sectional view of a sensor module that includes a sensor system package incorporating reflective surfaces on the interior upper walls of the inner cavity in accordance with the present invention;

FIG. 19B illustrates two light rays with different central wavelengths λ1 and λ2 entering the sensor module of FIG. 19A through the package aperture in accordance with the present invention;

FIG. 19C provides a side cross-sectional view of another example sensor module that includes a sensor system package incorporating reflective surfaces on the interior upper walls of the cavity in accordance with the present invention;

FIG. 19D provides a side cross-sectional view of another example sensor module that includes a sensor system package incorporating reflective surfaces on the interior upper walls of the cavity in accordance with the present invention;

FIG. 19E provides a side cross-sectional view of an example sensor system that includes multiple sensor modules

FIG. 20 illustrates a sensor system combining a light detection system and a light source in accordance with the present invention;

FIG. 21 illustrates the use of a micro-grating array to produce a matrix of spectral patterns for projection on a scene in accordance with the present invention;

FIG. 22 illustrates the use of a diffractive element to produce a matrix of spectral patterns for projection on a scene in accordance with the present invention;

FIG. 23 is a cross section view of an example light source module in accordance with the present invention;

FIG. 24 illustrates a light source incorporating a spectrometer with a light emitting element in accordance with the present invention;

FIG. 25A illustrates another sensor system combining a light detection system and a light source in accordance with the present invention;

FIGS. 25B and 25C provide a side-view of a sensor system combining a light detection system and a light source for calibration with a bi-modal shutter in accordance with the present invention;

FIG. 25D provides a logic diagram of a method for calibrating a spectral sensor in accordance with the present invention;

FIG. 25E provides a logic diagram of another method for calibrating a spectral sensor in accordance with the present invention;

FIGS. 25F and 25G provide a side-view of another sensor system combining a light detection system and a light source for calibration with a bi-modal shutter in accordance with the present invention;

FIG. 26A provides a side-view of a spectrometer system illustrating changes to measured center wavelengths based on the angle of incidence of incoming light in accordance with the present invention;

FIG. 26B provides a side-view of another spectrometer system illustrating changes to measured center wavelengths based on the angle of incidence of incoming light in accordance with the present invention;

FIG. 26C provides a top-down view of an offset aperture with respect to the center of a macro-pixel in accordance with the present invention;

FIG. 26D provides a side-view of a spectrometer system illustrating macro-pixels associated with interference-based filters and apertures in accordance with the present invention;

FIG. 26E provides a side-view of the example spectrometer system of 26D illustrating light propagation with reflective apertures in accordance with the present invention;

FIG. 26F provides a side-view of another spectrometer system illustrating macro-pixels associated with interference-based filters and apertures in accordance with the present invention;

FIG. 26G provides a side-view of another spectrometer system illustrating macro-pixels associated with interference-based filters and apertures in accordance with the present invention;

FIGS. 26H and 26I provide side-views of a spectrometer system illustrating the use of a lens to control the angle of incidence received at a macro-pixel in accordance with the present invention;

FIG. 26J provides a side-view of a spectrometer system illustrating the use micro-lenses to control the angle of incidence received at a macro-pixel in accordance with the present invention; and

FIG. 26K provides a side-view of another spectrometer system illustrating the use micro-lenses to control the angle of incidence received at a macro-pixel in accordance with the present invention.

### DETAILED DESCRIPTION OF THE INVENTION

In various embodiments, digital image sensors are combined with absorption type color filters for spectral sensing. In some embodiments digital image sensors are combined with absorption type color filters in a spectrometer module and with additional optical and/or electronic elements. In other embodiments, absorption type color filters and interference-based filters are combined with other optical and/or electronic elements to provide additional functionality and/or performance utilizing various form factors, including, but not limited to, spectrometer modules, and light source modules.

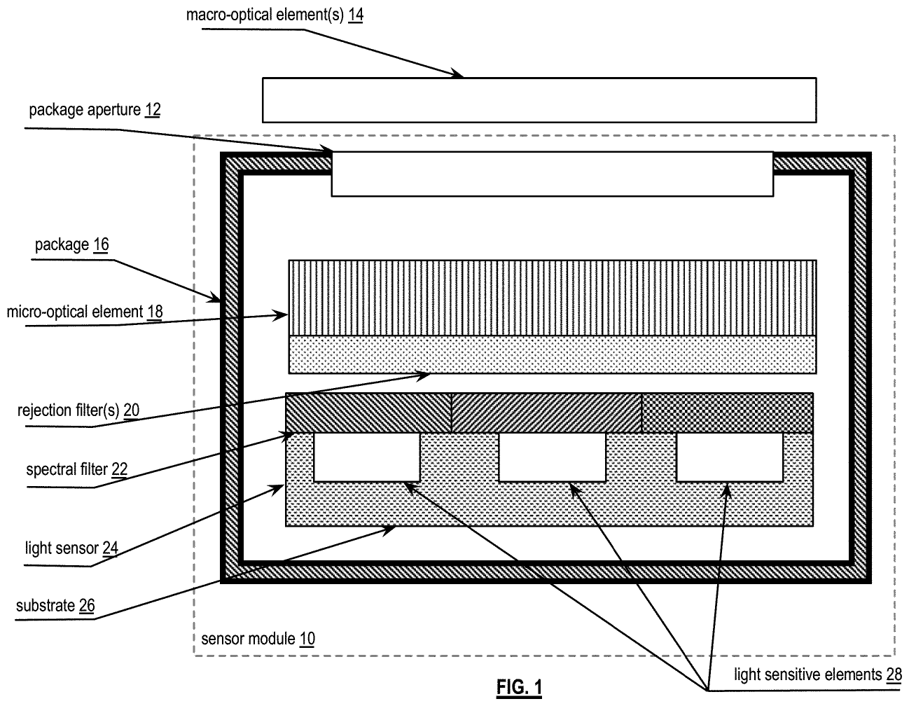

FIG. 1 provides a side cross-sectional view of a sensor module 10 that includes a package 16 incorporating a package aperture 12. In an example, incident light enters the package through package aperture 12, where it is ultimately collected at light sensor 24. In most examples herein, package aperture 12 is used synonymously with “pinhole”, where the pinhole is various dimensions as appropriate for the application described. Package 16 can be constructed of various opaque or semi-opaque materials, including metals, composites and synthetic or semi-synthetic organic compounds, along with combinations of same. In an example, package aperture 12 can be adapted to include a material capable of passing light, including glass (such as quartz or SiOₓ), clear synthetic or semi-synthetic organic compounds (such as cellophane, vinyl or plexiglass) or any other material that does not significantly absorb light within wavelengths of interest for the spectral sensor module 10. Package aperture 12 can be adapted to prevent foreign materials from entering the cavity defined by package 16, or it can be a simple opening for light entering the cavity. In another example, the package aperture 12 can be adapted to provide additional functionality, such as variable opening size (variable aperture), light focusing, and rejection of selected optical wavelengths and/or electromagnetic radiation.

Light sensor 24 includes light sensitive elements (sensors) 28 embedded in a substrate 26. In an example, light sensitive elements 28 can be any of complementary metal oxide semiconductor (CMOS) sensors, charge-coupled device (CCD) sensors and colloidal or quantum dot-based optical sensors, along with combinations of these sensors. In an example, light sensitive elements 28 can be configured to detect light in the visible, near-infrared (NIR), mid-infrared (MIR) or ultraviolet (UV) or combinations from this group. In an example, spectral filter 22 comprises multiple spectral filter elements integrated on light sensor 24. In a specific example, spectral filter 22 comprises a plurality of filters adapted to pass light in a spectrum of light wavelengths and is manufactured on top of light sensor 24, subsequent to back-end-of line (BEOL) processing of light sensor 24. In an example, an integrated spectral filter 22 includes multiple spectral filter elements, each associated with one or more light sensitive elements 28. In a specific example, the integrated spectral filter elements of spectral filter 22 can include different filter types, including interference filters, such as Fabry-Perot filters and absorption filters, such as plasmonic filters and quantum dot filters, either alone or in combination.

Sensor module 10 can include additional optical elements, such as rejection filter 20 and micro-optical element 18, located within the cavity of sensor module 10. In an example, rejection filter 20 can include a plurality of rejection filter elements, while micro-optical element 18 can include micro lenses, micro apertures, diffusers and other related optical elements. In an specific example of implementation, sensor module 10 is implemented as a sensor system including macro-optical element 14. In another example, macro-optical element 14 can be a single element or a plurality of optical elements that are each larger than the individual elements of micro-optical element 18.

In a specific example of implementation and operation, a package 16 can have a respective top surface, a respective bottom surface and a respective plurality of side surfaces with the top surface including a package aperture 12, with the top surface, the plurality of side surfaces and the bottom surface forming a cavity. In an example, a substrate 26 has a respective bottom surface and a respective top surface located within the cavity of package 16, the bottom surface of the substrate 26 being coupled to the interior bottom surface of the package 16 and a plurality of light sensitive elements 28 are located on the top surface of the substrate 26. In the example, a plurality of sets of spectral filters (spectral filter 22) having a respective top surface and a respective bottom surface are located atop the plurality of light sensitive elements 28, where each set of spectral filters of the plurality of sets of optical filters includes a plurality of spectral filters that are arranged in a pattern and where each spectral filter of the plurality of spectral filters is configured to pass light in a different wavelength range.

In a related example, one or more rejection filters is configured as a layer (such as rejection filter 20) having a respective top surface and a respective bottom surface, the bottom surface of the one or more rejection filters being proximate to the top surface of the plurality of sets of spectral filters. In an example, a cover is located at least partially within the package aperture 12 and in a specific example, one or more macro-optical elements 14 are located within the cavity of package 16. In an example, macro-optical element 14 is a single lens or a collection of lenses adapted to direct light through package aperture 16. In another example, macro-optical element 14 is a diffuser. In yet another example, macro-optical element 14 is a diffuser coupled to a single lens or a collection of lenses.

In a specific example of implementation an operation the wavelength sensitivity of a light sensitive element, such as one or more of light sensitive elements 28 is matched to a particular spectral filter element of spectral filter 22 to provide a light sensitive element and optical filter pair. In an example, the quantum efficiency of a particular light sensitive element (such as one or more of light sensitive elements 28) is adapted to be sensitive within a predetermined wavelength range by adjusting the full-well, the conversion gain and/or the area of the particular light sensitive element. In a related example, a sensor system includes a plurality of sets of optical filters, where a set of optical filters of the plurality of sets of optical filters includes a plurality of optical filters that are arranged in a pattern, where each optical filter of the plurality of optical filters is configured to pass light in a different wavelength range.

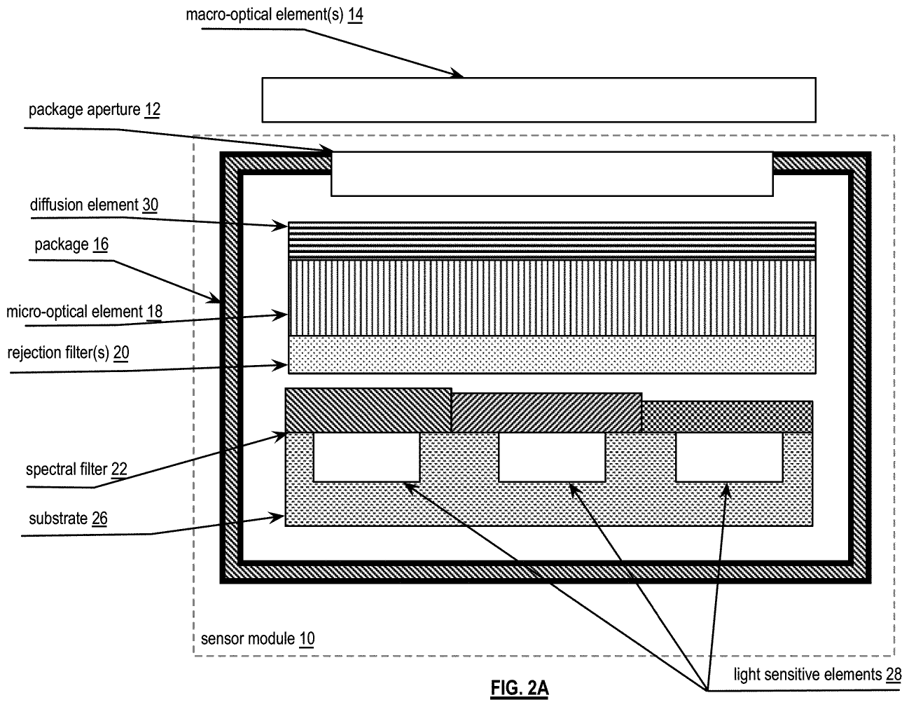

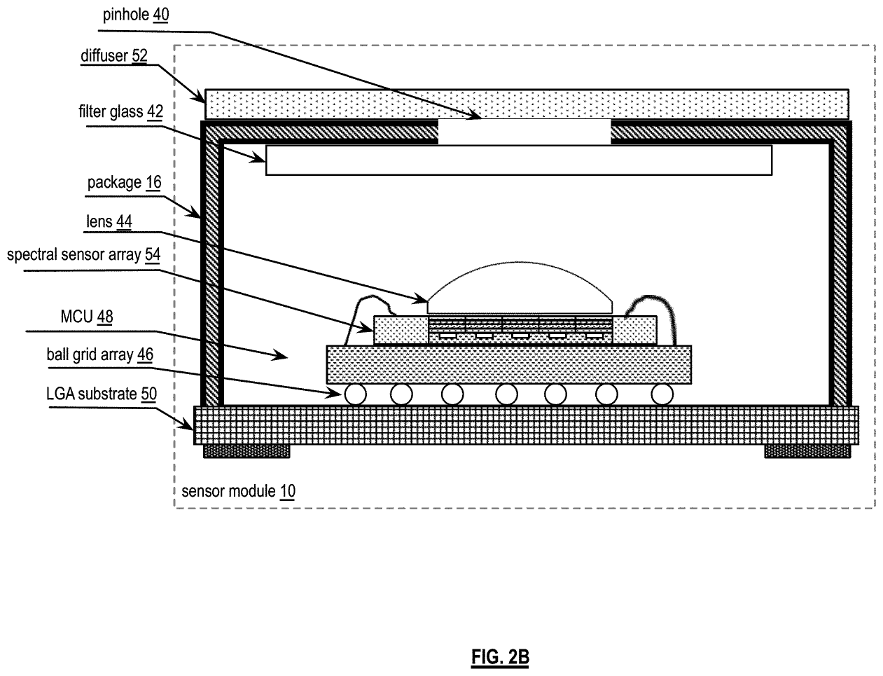

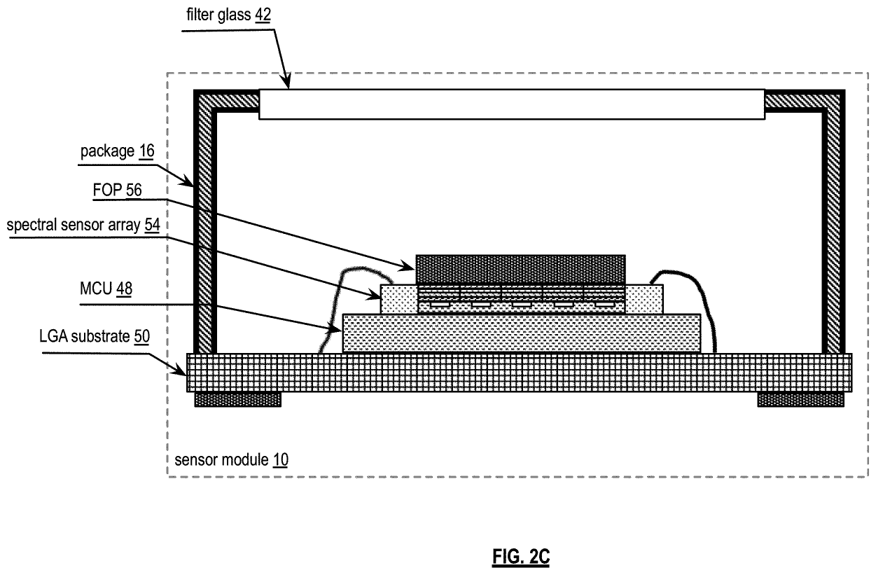

FIG. 2A provides a side cross-sectional view of another sensor module that includes a package incorporating a package aperture. In the example, incident light enters the package through package aperture 12, where it is ultimately collected at light sensor 24. Referring to FIG. 1, package 16 can be constructed of various opaque or semi-opaque materials, including metals, composites and synthetic or semi-synthetic organic compounds, along with combinations of the same. In an example, package aperture 12 can be adapted to include a material capable of passing light, including glass (such as quartz or SiOₓ), clear synthetic or semi-synthetic organic compounds (such as cellophane, vinyl or plexiglass) or any other material that does not significantly absorb light within wavelengths of interest for the spectral sensor module 10. Package aperture 12 can additionally be adapted to prevent foreign materials from entering the cavity defined by package 16; alternatively, package aperture 12 can be a simple opening for light entering the cavity. In another example, the package aperture 12 can be adapted to provide additional functionality, such as variable opening size (variable aperture), light focusing, and rejection of selected optical wavelengths and/or electromagnetic radiation.

Light sensor 24 includes light sensitive elements 28 embedded in a substrate 26. In an example, light sensitive elements 28 can be any of complementary metal oxide semiconductor (CMOS) sensors, charge-coupled device (CCD) sensors and colloidal or quantum dot-based optical sensors, along with combinations of these sensors. In an example, light sensitive elements 28 can be configured to detect light in the visible, near-infrared (NIR), mid-infrared (MIR) or ultraviolet (UV) or combinations from this group. In an example, spectral filter 22 comprises multiple spectral filter elements integrated on light sensor 24. In a specific example, spectral filter 22 comprises a plurality of optical filters adapted to pass light in a spectrum of light wavelengths and is manufactured on top of light sensor 24 subsequent to back-end-of line (BEOL) processing of light sensor 24. In an example, an integrated spectral filter 22 includes multiple spectral filter elements, each associated with one or more light sensitive elements 28. In a specific example, the integrated spectral filter elements of spectral filter 22 can include different filter types, including interference filters, such as Fabry-Perot filters and absorption filters, such as plasmonic filters and quantum dot filters, either alone or in combination.

Sensor module 10 can include additional optical elements, such as rejection filter 20 and micro-optical element 18 located within the cavity of sensor module 10. In an example, rejection filter 20 can include a plurality of rejection filter elements, while micro-optical element 18 can include micro lenses, micro apertures, and other related optical elements. In a specific example, micro-optical element 18 can comprise a fiber-optic plate. In specific example of implementation, sensor module 10 is implemented as a sensor system including micro-optical element 18 with a diffusion element 30, where the diffusion element 30 is located between aperture 12 and micro-optical element 18. In an example, diffusion element 30 (also called a light diffuser or optical diffuser) can comprise any material that diffuses or scatters light. In an example, diffusion element 30 comprises translucent material, including, but not limited to, ground glass, Teflon, opal glass, and greyed glass, located between a light source and the diffused light. In an example, the diffusion element 30 is adapted to scramble incident light before it is received at micro-optical element 18. In an example, diffusion element 30 can be a single element and in another example, diffusion element 30 can include a plurality of diffuser elements.

In a specific example of implementation and operation, a package 16 has a respective top surface, a respective bottom surface and a respective plurality of side surfaces with the top surface including a package aperture 12, the top surface, the plurality of side surfaces and the bottom surface forming a cavity. In an example, a substrate 26 having a respective bottom surface and a respective top surface is located within the cavity of package 16, the bottom surface of the substrate 26 being coupled to the interior bottom surface of the package 16 and a plurality of light sensitive elements 28 located on the top surface of the substrate 26. In the example, a plurality of sets of spectral filters 22 having a respective top surface and a respective bottom surface are located atop the plurality of light sensitive elements 28, where each set of spectral filters of the plurality of sets of optical filters includes a plurality of spectral filters that are arranged in a pattern and where each spectral filter of the plurality of spectral filters is configured to pass light in a different wavelength range.

In a related example, one or more rejection filters 20 are configured as a layer having a respective top surface and a respective bottom surface, the bottom surface of the one or more rejection filters being proximate to the top surface of the plurality of sets of spectral filters. In an example, one or more macro-optical elements 18 are located within the cavity of package 16 and diffusion element 30 is located between aperture 12 and micro-optical element 18. In an example, macro-optical element 18 is a fiber-optic plate.

In a specific example of implementation an operation, the wavelength sensitivity of a light sensitive element, such as one or more of light sensitive elements 28 is matched to a particular spectral filter element of spectral filter 22 to provide a light sensitive element and optical filter pair. In an example, the quantum efficiency of a particular light sensitive element (such as one or more of light sensitive elements 28) is adapted to be sensitive within a predetermined wavelength range by adjusting the full-well, the conversion gain and/or the area of the particular light sensitive element. In a related example, a sensor system includes a plurality of sets of optical filters, where a set of optical filters of the plurality of sets of optical filters includes a plurality of optical filters that are arranged in a pattern, where each optical filter of the plurality of optical filters is configured to pass light in a different wavelength range.

In an example, a plurality of sets of light sensitive elements includes a set of light sensitive elements of the plurality of sets of light sensitive elements, where a set includes a plurality of light sensitive elements arranged in a pattern and each light sensitive element of a set of light sensitive elements is substantially configured for peak quantum efficiency in a different wavelength range. In a specific example, each light sensitive element comprises a diffusion well, with each light sensitive element of a set of light sensitive elements configured for substantially peak quantum efficiency based on the dimensions of the diffusion well. In a specific example, the dimensions of the diffusion well include a depth D, where the peak quantum efficient for each light sensitive element is at least partially based on the depth D. In another specific example, the dimensions of the diffusion well include an area A, where the peak quantum efficient for each light sensitive element is at least partially based on the area A. In yet another specific example, each light sensitive element of a set of light sensitive elements includes a conversion gain C, where the peak quantum efficient for each light sensitive element is at least partially based on the conversion gain C.

In an example, each light sensitive element is associated with one or more optical filters of a set of optical filters to create a light sensitive element and optical filter pair, where the peak quantum efficiency for the light sensitive element of a light sensitive element and optical filter pair is matched to the wavelength range of light passed by the one or optical filters of the light sensitive element and optical filter pair.

FIG. 2B provides a side cross-sectional view of another example sensor modules. FIG. 2A provides a side cross-sectional view of another sensor module that includes a package incorporating a package aperture (pinhole 40). In the example, incident light enters the package through pinhole 40, where it is ultimately collected at light sensor array 54. Referring to FIG. 1, package 16 can be constructed of various opaque or semi-opaque materials, including metals, composites and synthetic or semi-synthetic organic compounds, along with combinations of the same. In an example, diffuser 52 and/or filter glass 42 is provided to prevent foreign materials from entering the cavity defined by package 16. In another example, the pinhole 40 can be adapted to provide additional functionality, such as variable opening size (variable aperture), light focusing, and rejection of selected optical wavelengths and/or electromagnetic radiation.

Spectral sensor array 54 includes light sensitive elements embedded in a substrate (such as substrate 26 from FIG. 2A). In an example, spectral sensor array 54 comprises multiple spectral filter elements integrated with sensor elements, such as any of the sensor elements of FIGS. 1 and 2A.

Sensor module 10 can include additional elements, such as a micro controller unit (MCU) 48. In an example, the MCU 48 can be a processor adapted to receive output from the spectral sensor array 54. In an example, MCU 48 can be adapted to process and/or calibrate the sensor output to provide one or more optical spectra. In a specific example of implementation, MCU 48 is coupled to land-grid-array (LGA) 50. In an example, MCU 48 is electrically coupled to LGA substrate 50 via a solder connection using, for example, a ball grid array. In a related example, MCU 48 is coupled to LGA substrate 50 and spectral sensor array 54 is coupled to MCU 48 to provide a single unit. In a related example, spectral sensor array 54 is wire bonded to LGA substrate 50, allowing electrical communication between spectral sensor array 54 and MCU 48, along with electrical communication with components/elements outside of sensor module 10. In yet another specific example, LGA substrate 50 can be adapted to provide both a bottom surface for the package 16 and electrical connections for MCU 48 and spectral sensor array 54.

In an example, lens 44 is adapted to provide substantial collimation and/or confinement of light entering the sensor through pinhole 40. In an example of implementation, lens 44 can be coupled to spectral sensor array 54 using an adhesive, such, for example, an adhesive adapted for optical applications. In another example, lens 44 can be mounted with an airgap between the bottom surface of lens 44 and spectral sensor array 54, with the lens mounted, for example, to one or more inner sidewalls of the package 16. Diffuser 52 can comprise any material that diffuses or scatters light, such as any of the diffuser materials referred to in FIGS. 1 and/or 2A. In an example, diffuser 52 can be a single element and in another example, diffuser 52 can include a plurality of diffuser elements. In yet another example of implementation, lens 44 is excluded from sensor module 10 altogether, or implemented outside of sensor module 10.

FIG. 2C provides a side cross-sectional view of another sensor module that includes a package aperture at or near the outside boundaries of package 16. In the example, incident light enters the package through filter glass 42, where it is ultimately collected at sensor array 54. In an example, filter glass 42 can be adapted to include a material capable of passing light, including glass (such as quartz or SiOₓ), clear synthetic or semi-synthetic organic compounds (such as cellophane, vinyl or plexiglass) or any other material that filters light outside the wavelengths of interest for the spectral sensor module 10. Filter glass 42 can additionally be adapted to prevent foreign materials from entering the cavity defined by package 16.

In a specific example, a fiber-optic plate (FOP) 56 can be located between the filter glass 42 and spectral sensor array 54. In specific example of implementation, fiber-optic plate 56 can be adapted to substantially collimate light passing through filter glass 42 before it is collected at spectral sensor array 54. In another example, a light diffuser can be coupled to one or more of the top surface of FOP 56, the top surface of filter glass 42 or outside of sensor module 10.

FIG. 2D FIG. 2A provides a side cross-sectional view of another sensor module that includes a filter glass 42 mounted substantially in a package aperture for package 16. In the example, a fiber-optic plate (FOP) 56 can be located between the filter glass 42 and spectral sensor array 54. In an example, incident light enters the package through filter glass 42 and is collimated by fiber-optic plate 56, to be ultimately collected at spectral sensor array 54. In an example, package 16 defines a cavity that includes all the elements of filter glass 42, fiber-optic plate 56, spectral sensor array 54, and MCU 48. In a related example, package 16 can be adapted to fill in any space not occupied within the inner boundaries of package 16. In another example, a light diffuser can coupled to one or more of the top surface of FOP 56 (between FOP 56 and filter glass 42), the top surface of filter glass 42 or outside of sensor module 10.

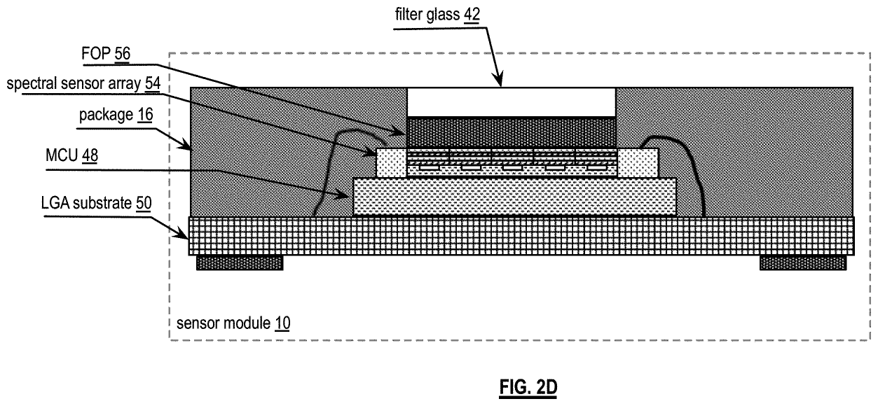

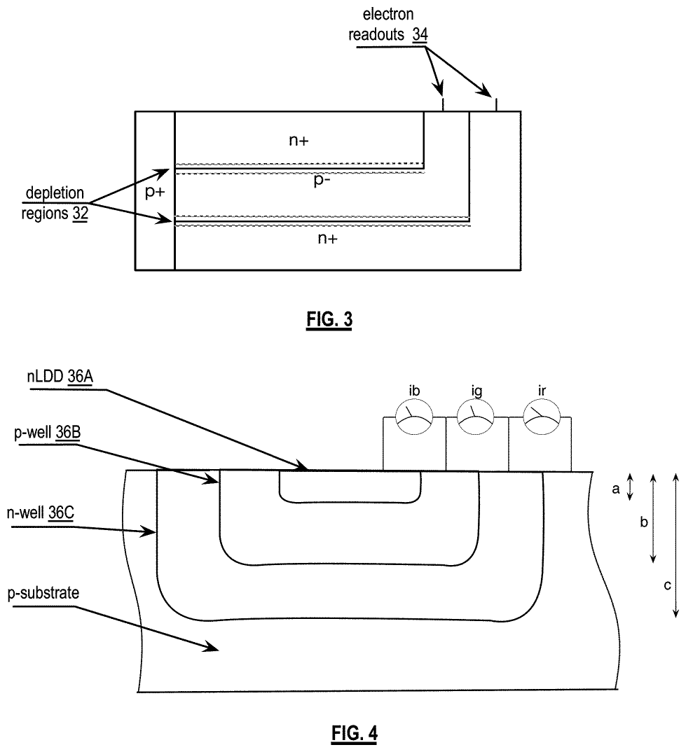

FIG. 3 illustrates another example multi junction photodiode configured to select different interference harmonics for a given interference filter, such as a Fabry-Perot filter. In an example, a multi junction photodiode includes multiple wells located at different depths within the substrate. In an example, associated interference filter harmonics for a given interference filter have specific penetration depths and therefore are each detected at a different well of the multi-junction photodiode. In the example a light sensitive element includes multiple depletion regions. In an example, the depletion regions 32 are insulating regions within a conductive, doped semiconductor material where the mobile charge carriers have been forced away by an electric field. In an example, the elements left in the depletion regions 32 are limited to primarily ionized donor or acceptor impurities. Accordingly, the depletion regions 32 are formed from a conducting region by removal of all free charge carriers, leaving none to carry a current. In an example, electron readouts 34 are configured to measure a voltage and or current in response to photons absorbed at depletion regions 32.

In a specific example of implementation and operation, an optical sensor system includes a semiconductor substrate having a respective top surface and a plurality of interference filters having a respective top surface and a respective bottom surface, where the bottom surface of the plurality of interference filters is located proximal to the top surface of a plurality of optical sensors implemented as a layer having a respective top surface, where each optical sensor of the plurality of optical sensors comprises a plurality of wells, where each well of the plurality of wells has a respective top surface and a respective bottom surface and the respective bottom surface for each well of each of the plurality of wells is at a different depth under the top surface of the substrate.

In a related example, each interference filter of the plurality of interference filters is configured to pass light in one of a plurality of wavelength ranges. In another example, each well of the plurality of wells is configured to provide a depletion region correlated to a harmonic corresponding to a harmonic of an associated interference filter. In a specific related example, the depth for each well is adapted to enable the detection of light at a different harmonic of a center wavelength (CWL) of light passing through an associated one or more of the plurality of interference filters.

FIG. 4 illustrates another example multi junction photodiode configured to select different interference harmonics, either with or without the use of an interference filter. In an example, the depth a of the nLDD well, the depth b of p-well 36B and the depth c of n-well 36C define the depletion regions where photons for blue, green and red are absorbed and detected.

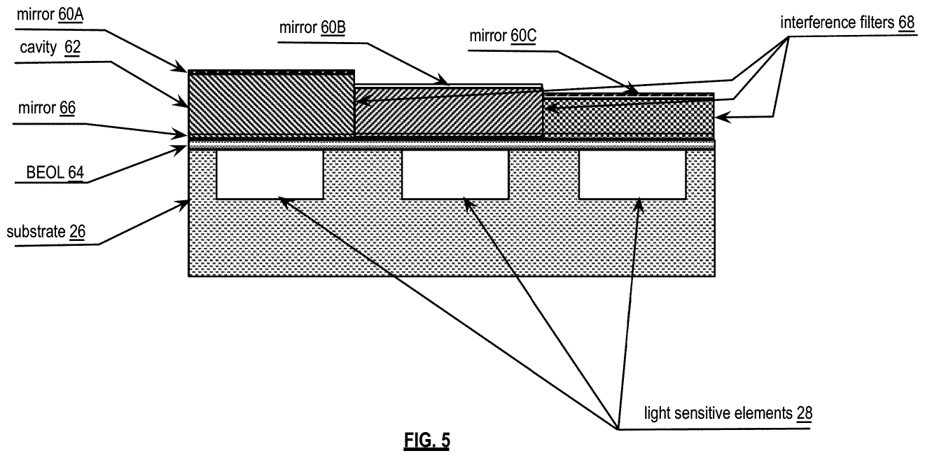

FIG. 5 provides a cross-sectional view of an integrated filter and sensor array. In the figure, substrate 26 includes a plurality of light sensitive elements 28 in a sensor array. Back-end-of-line (BEOL) layer 64 is located on substrate 26 with light sensitive elements 28 and is in turn covered by first mirror 66. Interference filters 68 each include a cavity 62 and a second mirror (mirror 60A-60C). In an example, cavity 62 is configured at a different thickness in each of interference filters 68 to pass light in a different wavelength range for each of light sensitive elements 28. In an example, the cavity material and/or either one of the first or second mirror material can be formed using atomic layer deposition and/or pulsed laser deposition. In an example, atomic layer deposition provides for precise deposition, including deposition of monoatomic layers.

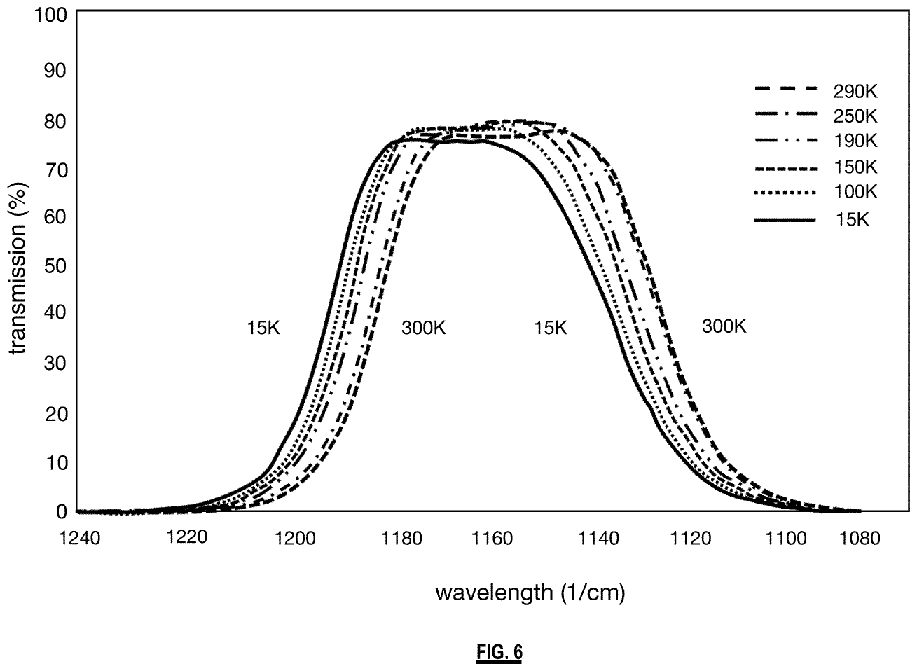

FIG. 6 provides an illustration of an example transmission output in the SWIR band. In the illustration the transmission from a 5% Full Width at Half-Maximum filter with double-order (λ) cavities is shown over a range of temperatures. In an example, non-CMOS based optical sensors (light sensitive) can be used to extend the spectral range of a spectral sensor to short-wave infrared (SWIR) wavelengths between approximately 1400 nm and 3000 nanometers (nm). For example, Germanium on Silicon (Ge-on Si) optical sensors can be used to collect light in the SWIR wavelength range. In an example, integrated filters are added on top of SWIR light sensitive elements to implement a spectrometer that is sensitive in SWIR wavelengths. In another example, SWIR light sensitive elements can be used to implement an image sensor. In an example, a sensor system can include a plurality of sets of optical sensors, where each set of optical sensors is arranged in a pattern. In yet another example, integrated filters and SWIR light sensitive elements combine to create a hyperspectral imager (HSI) or a spectrometer in the SWIR region. In a specific example of implementation, optical sensors are made up of a stack that includes Indium Gallium Aluminum and Arsenic. In an example, the stack is InₓGa_{y}Al_{z}As, where x, y and z are parameters indicating the ratios present in the alloy. In an example, InₓGa_{y}Al_{z}As has a high refractive index making it ideal for matching with an integrated filter stack. In another example, graphene sensors may be used.

In an example of operation and implementation, A spectrometer system includes a plurality of short-wave infrared (SWIR) sensors on an integrated circuit and a plurality of sets of interference filters atop the plurality of SWIR sensors, where a set of interference filters of the plurality of sets of interference filters includes a plurality of interference filters that are arranged in a pattern and each interference filter of the plurality of filters is configured to pass light in a different wavelength range. In an example, each set of interference filters of the plurality of interference filters is associated with a set of SWIR sensors. In a specific related example, the SWIR sensors are Germanium on Silicon (Ge-on Si) sensors. In another example, the SWIR sensors comprise Indium Gallium Aluminum and Arsenic. In yet another specific example, one or more interference filters of a set of interference filters comprise InₓGa/AlAs/oxide that are fabricated over an array of light sensitive elements made of InₓGa_{y}Al_{z}As.

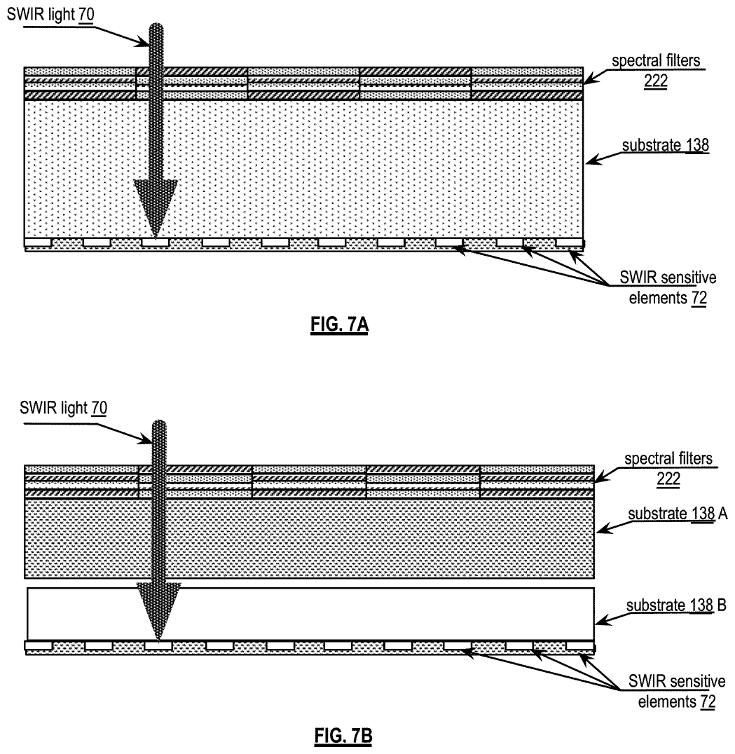

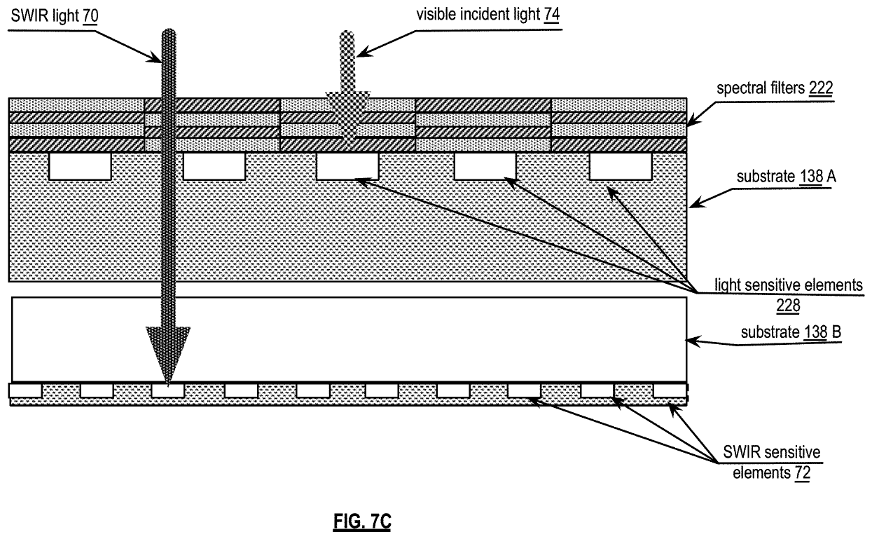

Semiconductor substrates, such as single crystal silicon substrates can be substantially transparent to short-wave infrared (SWIR) wavelengths. FIG. 7A provides a side-view of an imaging device for detecting SWIR light wavelengths, such as SWIR light 70. In the example, a silicon substrate 138 includes a top and bottom surface with one or more spectral filters 222 located on a respective top surface and one or more SWIR sensitive elements 72 located on a respective bottom surface of the silicon substrate. In an example, incoming incident light can be filtered by the spectral filters 222 on the top surface of the substrate and detected by the SWIR sensitive elements 72 on the bottom surface of the substrate. In an example, the SWIR sensitive elements 72 can comprise any of the materials described above, as well as InGaAs and/or HgCdTe (MCT). In an example, the spectral filters 222 can comprise any filter or combination of filters that selectively transmit light in SWIR wavelengths, including, but not limited to, interference filters, absorption filters and plasmonic filters.

In a specific example of implementation, SWIR filters (such as spectral filters 222) are fabricated on the top surface of a semiconductor substrate 138 first, with thin film photosensors (such as SWIR sensitive elements 72) adapted to be sensitive to SWIR wavelengths fabricated subsequently on the bottom surface in a separate process. In a specific related example, the thin film photosensor fabrication includes deposition of one more thin film materials at a temperature that is lower than the process used to fabricate the SWIR filters. In a specific example of operation and implementation, a spectrometer system includes a plurality of short-wave infrared (SWIR) sensitive elements on the backside of an integrated circuit and a plurality of sets of interference filters on the top side of the integrated circuit, where a set of interference filters of the plurality of sets of interference filters includes a plurality of interference filters that are arranged in a pattern and each interference filter of the plurality of filters is configured to pass light in a different wavelength range. In a specific example, each set of interference filters of the plurality of interference filters is associated with a set of SWIR sensors on the backside of the integrated circuit. In a specific example, the integrated circuit is configured to read out a signal from the thin-film photosensors.

FIG. 7B provides a side-view of another imaging device for detecting SWIR wavelengths. In the example, a first semiconductor substrate 138A includes a top and bottom surface with one or more spectral filters 222 located on a respective top surface, while a second semiconductor substrate includes respective top and bottom surfaces with one or more SWIR sensors (such as SWIR sensitive elements 72) located on a respective top surface of the second semiconductor substrate 138B. In an example, the bottom surface of semiconductor substrate 138A is located proximate to the top surface of semiconductor substrate 138B, such that incoming incident light can be filtered by the interference filters on top surface of semiconductor substrate 138A and detected by the SWIR sensors on the top surface of semiconductor substrate 138B. In an example, a resultant substrate stack or sandwich can be coupled using an adhesive material, by wafer bonding or by mechanically coupling the two surfaces (or any combination thereof). In an example, the SWIR sensors can comprise any of the materials described above with reference to FIGS. 7A and 7B, as well as InGaAs and/or HgCdTe (MCT). In an example, the SWIR filter can comprise any filter or combination of filters that selectively transmit light in SWIR wavelengths, including, but not limited to, interference filters, absorption filters and plasmonic filters. In an alternative example, the interference filter array of FIG. 7B includes the top surface of the first semiconductor substrate located proximate to the bottom surface of the second semiconductor substrate, such that incoming incident light can be filtered by the interference filters after passing through the first semiconductor substrate and detected by the SWIR sensors on the top surface of the second semiconductor substrate, potentially reducing crosstalk between filters.

In an example of operation and implementation, a spectrometer system includes a plurality of short-wave infrared (SWIR) sensors on the top side of a first integrated circuit and a plurality of sets of interference filters on the top side of a second integrated circuit, where a set of interference filters of the plurality of sets of interference filters includes a plurality of interference filters that are arranged in a pattern and each interference filter of the plurality of filters is configured to pass light in a different wavelength range. In an example, the bottom sides of both the first and second integrated circuits are located such that the bottom side surfaces of the first and second integrated circuits are parallel and in close proximity to each other. In a specific example, each set of interference filters of the plurality of interference filters is associated with a set of SWIR sensors on the backside of the integrated circuit. In another example, the bottom side surfaces of the first and second integrated circuits are coupled to each other using at least one of an adhesive, wafer bonding and mechanical coupling.

FIG. 7C provides a side-view of an imaging device for detecting both SWIR wavelengths and wavelengths in visible light wavelengths. In the example, a first semiconductor substrate (semiconductor substrate 138A) having a respective top and bottom surface with one or more spectral filters 222 is located atop an array of light sensitive elements 228 adapted for detection of wavelengths in visible light wavelengths, while a second semiconductor substrate (semiconductor substrate 138B) having a respective top and bottom surface includes one or more SWIR sensors located on the top surface. In an example, the bottom surface of the first semiconductor substrate is located proximate to the bottom surface of the second semiconductor substrate, such that incoming incident light in visible wavelengths (visible incident light 74) can be filtered by the interference filters on top surface and detected on the first semiconductor substrate, while wavelengths in the SWIR wavelength range (SWIR light 70) pass through the filters and sensors on the first semiconductor substrate and detected by the SWIR sensors on the top surface of the second semiconductor substrate. In an example, a resultant substrate stack or sandwich can be coupled using an adhesive material, by wafer bonding or mechanically coupling or any combination thereof. In an example, the SWIR sensors can comprise any of the materials described above with reference to FIGS. 7A and 7B, as well as InGaAs and/or HgCdTe (MCT). In an example, the SWIR filter can comprise any filter or combination of filters that selectively transmit light in SWIR wavelengths, including, but not limited to, interference filters, absorption filters and plasmonic filters. In an alternative example, the bottom surface of the first semiconductor substrate is located proximate to the top surface of the second semiconductor substrate, such that wavelengths in the SWIR wavelength range pass through the filters and sensors on the first semiconductor substrate and are detected by the SWIR sensors on the top surface of the second semiconductor substrate without passing through the substrate of the s second semiconductor substrate.

In an example, a resultant sensor system can be used to detect light in two ranges of wavelengths using a common architecture. In a related example, the resultant sensor system can achieve a substantially maximum fill factor. In an embodiment, the interference-based filters are designed to transmit in at least two wavelength channels, one in the visible range and another in the SWIR, the visible light will be detected by the visible sensors while the SWIR light will cross it and reach the SWIR sensors.

In a specific example of operation and implementation, a spectrometer system includes a plurality of short-wave infrared (SWIR) sensors on the top side of a first integrated circuit and a plurality of sets of interference filters atop a plurality of optical sensors on the top side of a second integrated circuit, where a set of interference filters of the plurality of sets of interference filters includes a plurality of interference filters that are arranged in a pattern and each interference filter of the plurality of filters is configured to pass light in a different wavelength range. In an example, the bottom sides of both the first and second integrated circuits are located such that the bottom side surfaces of the first and second integrated circuits are parallel and in close proximity to each other. In a specific example, the bottom side surfaces of the first and second integrated circuits are coupled to each other using at least one of an adhesive material, by wafer bonding, mechanically coupling or any combination thereof.

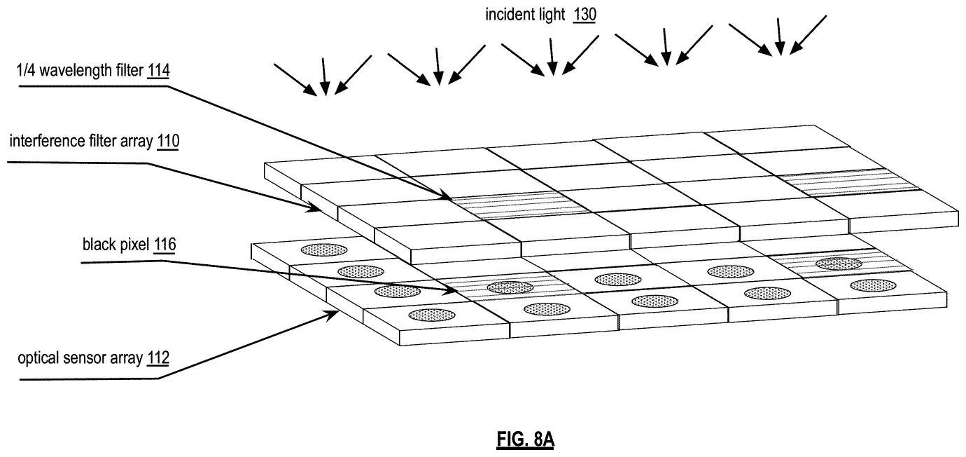

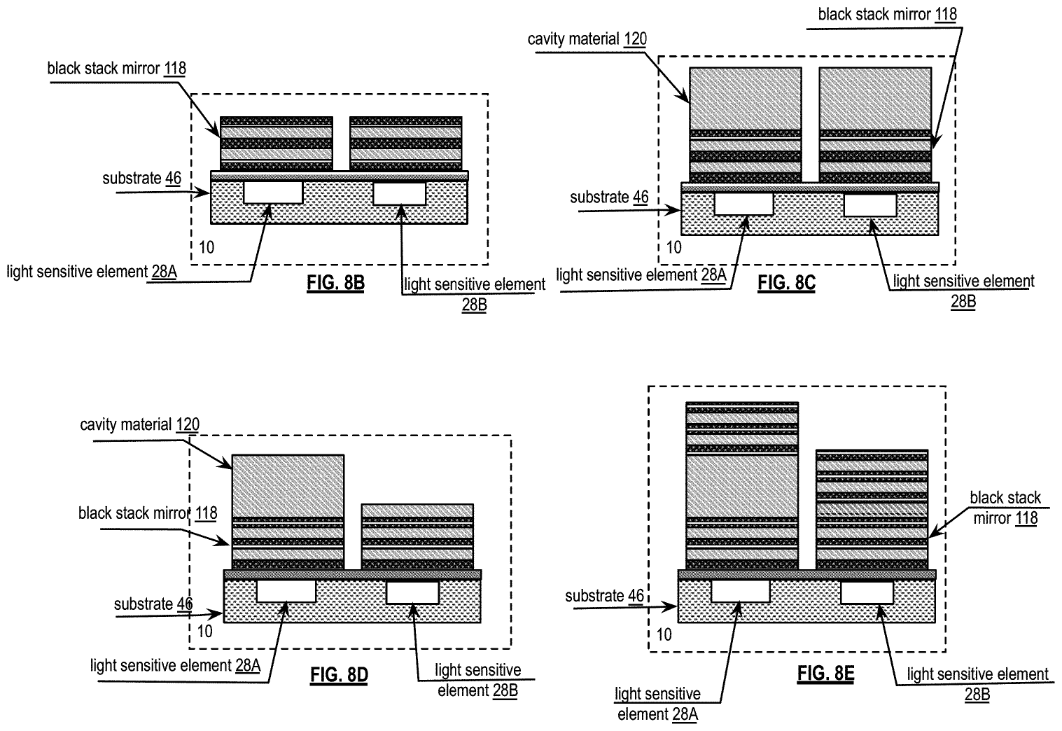

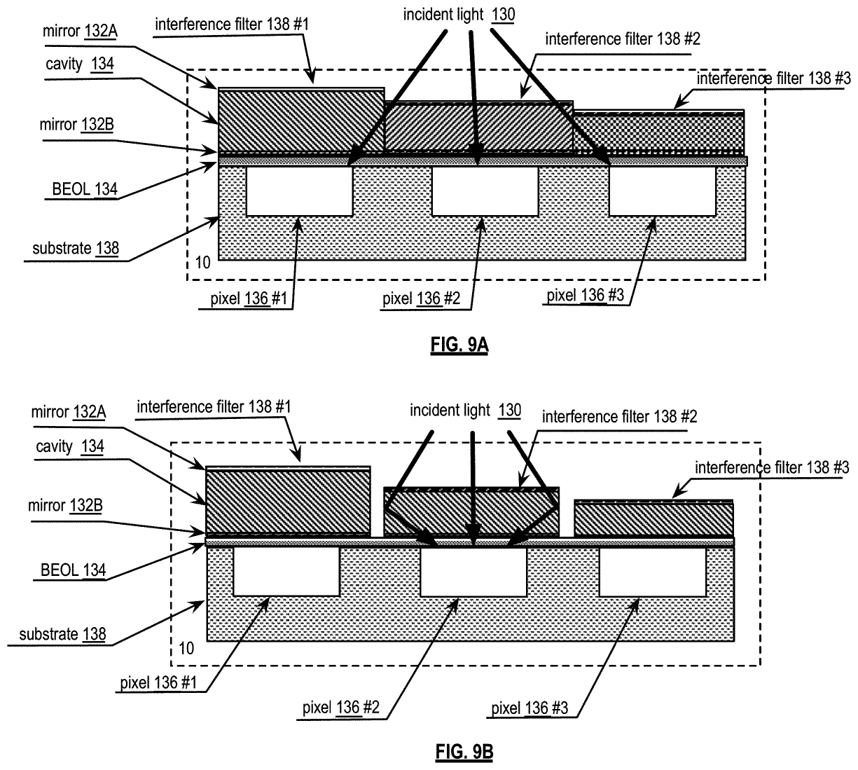

FIG. 8A provides an exploded side illustration of interference filters used to provide periodic black pixels on a sensor array. In an example, a sensor array incorporating pixels/sensors (pixels) that are insensitive to light at certain positions in the array can be provide useful for some applications. For example, the black pixels can be used to provide reference positions within the sensor array. In another example, since the black pixels receive little or no light the black pixels can be used to provide a reference output for calibration of adjacent pixels.

Referring to FIG. 8A, an optical sensor array 112 include light sensitive elements located below an interference filer array 110. Interference filter array 110 includes highly reflective interference filters 114 at predetermined locations within the array. In an example, each interference filter in interference array 110 is associated with a light sensitive element in optical sensor array 112. Interference array 110 is shown for illustration purposes separated from optical sensor array 112, however in practice the interference array 110 would be disposed directly on the surface of optical sensor array 112 or closely proximate thereto. The highly reflective interference filters 114 effectively blocks any light from passing through to the pixel below. In an example, the highly reflective interference filter 114 is a Fabry-Perot filter with a cavity sandwiched between two mirrors with a thickness of ¼ wavelength, making it highly reflective, effectively blocking light from passing to the pixel below.

FIGS. 8B-8D illustrate the process for forming a double Bragg stack mirror. In an example, black pixels can comprise a double Bragg stack mirror.

In a specific example of implementation and operation, a sensor system includes a plurality of optical sensors (light sensitive elements 28A-28B) arranged in an array on an integrated circuit substrate 46 with a plurality of sets of interference filters located atop the array of optical sensors. In the example, a set of interference filters of the plurality of sets of interference filters includes a plurality of interference filters that are arranged in a pattern, where each interference filter of the plurality of filters is configured to pass light in a different wavelength range and each set of interference filters of the plurality of interference filters is associated with a spatial area of a scene. In an example, a set of interference filters also includes an interference filter configured to substantially reflect light, where the interference filter configured to substantially reflect light is located in a predetermined position relative to the optical sensor array.

In an example, the interference filter configured to substantially reflect light (such as black stack mirror 118 in any of FIGS. 8B-8D) can comprise a double Bragg stack filter, where a double Bragg stack filter is an interference filter with a pair of mirrors separated by a cavity (such as cavity material 120 in any of FIGS. 8B-8D). In an example, one or more processors (not shown) are coupled to the sensor system 10, where the one or more processors are adapted to calibrate one or more optical sensors in the optical sensor array based on an output from an optical sensor associated with the interference filter configured to substantially reflect light.

In another specific example of operation and implementation, a method for forming an optical sensor comprises depositing a first mirror material on an array of light sensitive elements and continues with depositing a layer of cavity material atop the first mirror layer. The method then continues with selectively etching the cavity material at a plurality of predetermined positions on the array of light sensitive elements to substantially ¼ of a predetermined wavelength of light incident to the array. In an example, each predetermined position of the plurality of predetermined positions is associated with a light sensitive element of the array of light sensitive elements. The method then continues with a second mirror material being deposited on the etched cavity material.

FIG. 9A provides a side cross-sectional view of an integrated filter and sensor array. In the figure, substrate 138 includes a plurality of sensors (pixels 136 #1, 2 and #3) in a sensor array. Back-end-of-line (BEOL) layer 134 is located on substrate 138 with pixels 136 #1, 2 and #3 and is in turn covered by mirror 132B of interference filters 138 #1, 2 and #3. Interference filters 138 #1, 2 and #3 each include a cavity 134 and a top mirror 132A. In an example, cavity 134 is configured at a different thickness in each of interference filters 138 #1, 2 and #3 in order to pass light in a different wavelength range for each of underlying pixels 136 #1, 2 and #3. As illustrated, incident light 130 can pass through an interference filter, such as interference filter 138 #2 while being sensed at a pixel adjacent to the desired pixel, such as pixel 136 #1. In an example, these parasitic light wavelengths degrade sensor performance.

FIG. 9B provides another side cross-sectional view of an integrated filter and sensor array, where a channel has been etched out between adjacent interference filters. As in FIG. 9A, in the figure, substrate 138 includes a plurality of sensors (pixels 136 #1, 2 and #3) in a sensor array. Back-end-of-line (BEOL) layer 134 is located on substrate 138 with pixels 136 #1, 2 and #3 and is in turn covered by mirror 132B of interference filters 138 #1, 2 and #3. Interference filters 138 #1, 2 and #3 each include a cavity 134 and a top mirror 132A. In the example, cavity 134 is configured at a different thickness in each of interference filters 138 #1, 2 and #3 in order to pass light in a different wavelength range for each of underlying pixels 136 #1, 2 and #3 and a channel is etched between each of interference filters 138 #1, 2 and #3. As illustrated, instead of passing through an interference filter, such as interference filter 138 #2 and being sensed at a pixel adjacent to the desired pixel, incident light 130 is reflected at the sidewall of interference filter 138 #2 toward pixel 136 #2.

In an example referring to FIG. 9B, an air gap between interference filters 138 #1, 2 and #3 can create a light pipe between the interference filters, where the refractive index of the air serves to reject at least a portion of light arriving from undesired angles by inducing total internal reflection (TIR). In an example, TIR occurs when light waves in the cavity of an interference filter reach the boundary with the air at a sufficiently slanting angle, reflecting the light waves like a mirror. In another example, instead of an air gap, the void between interference filters 138 #1-#3 are filled with another material. In another example, the sidewalls of the interference at the boundary of the air gap (or void) not perpendicular to the substrate top surface.

In a specific example of implementation and operation, an optical sensor system, includes a plurality of optical sensors on an integrated circuit and a plurality of sets of interference filters, where a set of interference filters of the plurality of sets of interference filters includes a plurality of interference filters that are arranged in a pattern and each interference filter of the set of filters is configured to pass light in a different wavelength range. In an example, each interference filter has a respective top surface, a respective bottom surface and four respective side surfaces and each of the interference filters are separated on at least two side surfaces from adjacent interference filters by an air gap. In an example, the air gap is created using an etch process, where the etch process can be one or more of a liquid etch, plasma etching, including deep reactive ion etching (DRIE) and ion milling.

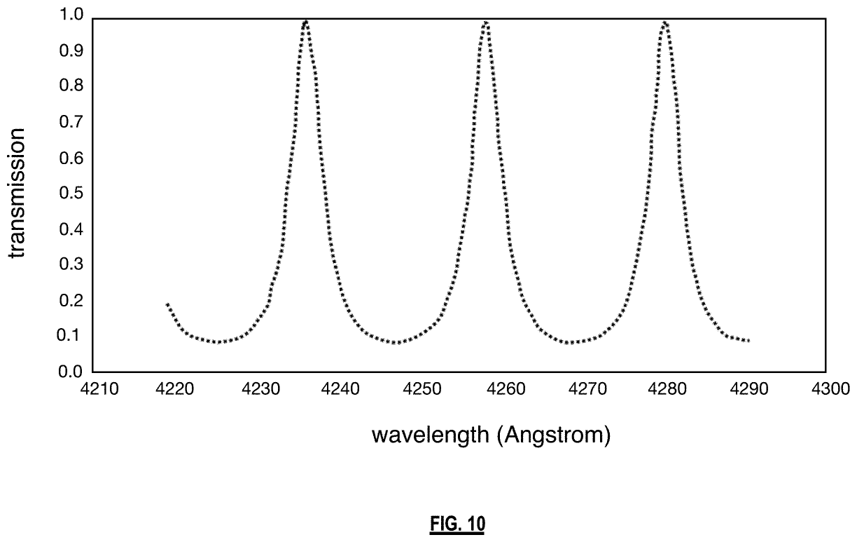

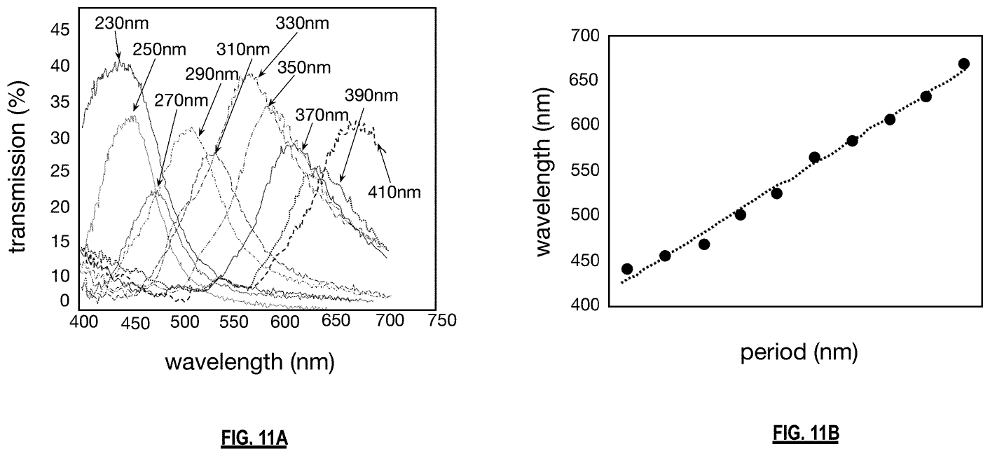

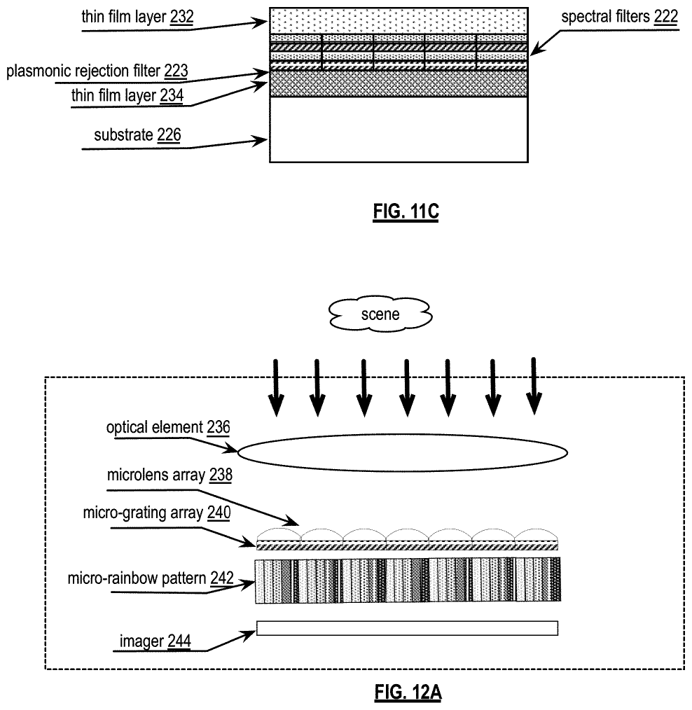

FIG. 10 provides an illustration of the spectral response of a Fabry-Perot interference filter showing transmission peaks for different orders of constructive interference. In an example, a typical optical rejection filter is designed to have a narrow transmission window that substantially limits transmission through the filter to wavelengths corresponding to a single order of the filter. In an alternative example, optical rejection filters having a broadband transmission window (wide band rejection filters) can allow parasitic signals to reach an interference filter, such as a Fabry-Perot filter, where the parasitic signals can be, for example, higher order harmonics of the Fabry-Perot filter. In an example of implementation, by properly combining wide band rejection filters and Fabry-Perot filters, parasitic signals can be utilized as additional wavelength windows.

In a specific related example of implementation, an optical sensor system includes an array of optical sensors arranged on an integrated circuit, the array of optical sensors having a respective top surface. In an example, the sensor system includes a plurality of sets of interference filters having a respective top surface and a respective bottom surface, where each interference filter of the set of filters is configured to pass light in a different wavelength range, where the bottom surface of the plurality of sets of interference filters is located proximal to the top surface of the array of optical sensors. In a further example, the sensor system includes one or more rejection filters, each having a respective top surface and a respective bottom surface, where the top surface and bottom surface of the one or more rejection filters are proximal to the top surface of the array of optical sensors, where each of the one or more rejection filters has a respective upper bandpass limit and a respective lower bandpass limit, and the one or more rejection filters are configured to substantially reject light wavelengths outside the upper bandpass limit and the lower bandpass limit. In an example, the upper bandpass limit and the lower bandpass limit of the one or more rejection filters are selected to pass wavelengths within a number X orders of constructive interference for light wavelengths passed by a corresponding interference filter of the set of interference filters. In a specific example, the number X orders of constructive interference for light wavelengths passed by the at least one interference filter includes at least one higher order harmonic of the corresponding interference filter. In another example, one or more optical sensors of the array of optical sensors is adapted to sense light wavelengths included in the number X orders of constructive interference for light wavelengths passed by at least one interference filter.

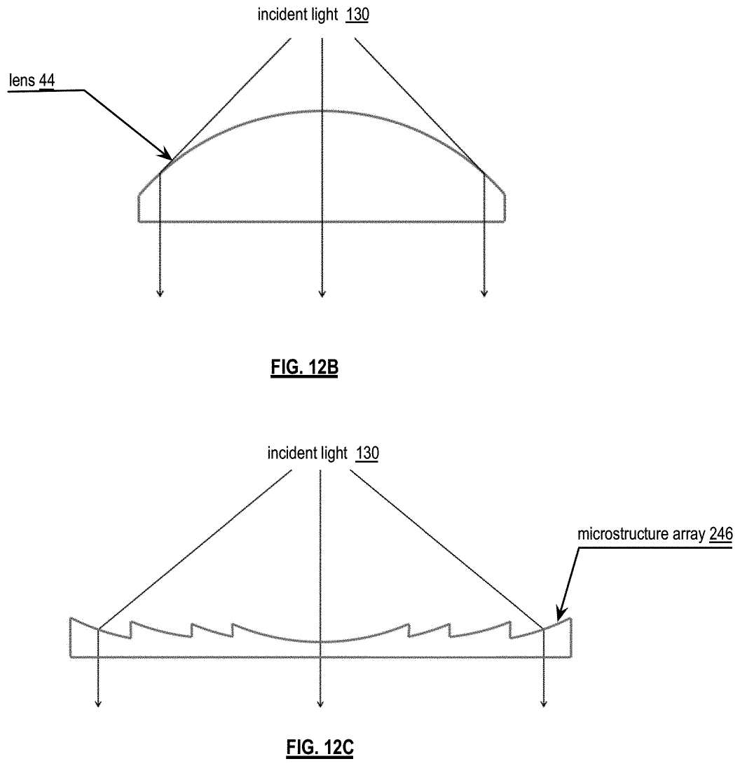

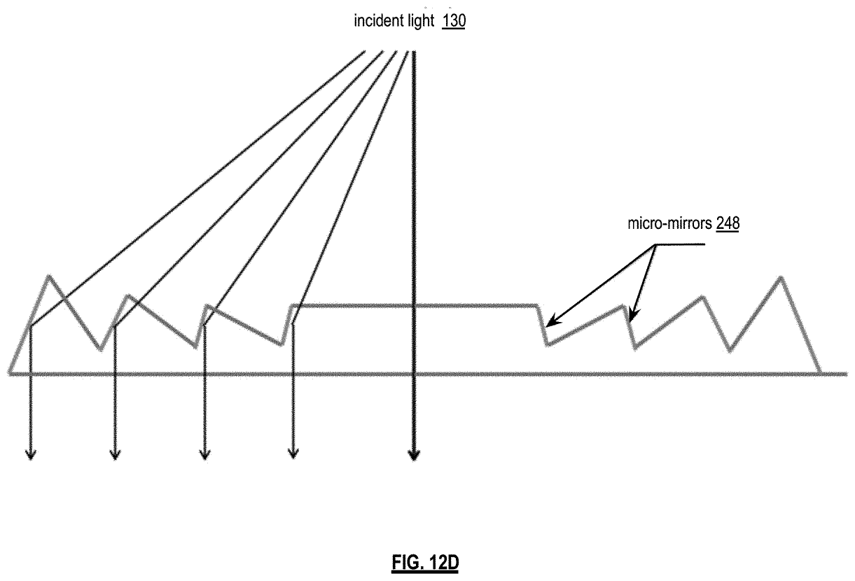

FIG. 11A illustrates transmissive spectra of example plasmonic filters, in this case consisting of periodic subwavelength holes in an aluminum film. FIG. 11B illustrates the respective transmission outputs for plasmonic filters across a given wavelength range. In the example, plasmonic filters are adapted to pass wavelengths for the plasmonic filters as a function of the period in nanometers (nm). As illustrated, plasmonic rejection filters can provide broad transmission bands. In an example of implementation, a plurality of plasmonic rejection filters can be integrated on interference filters. In a specific example, one or more plasmonic filters and one or more Fabry-Perot filters (or another interference filter type) can be paired to provide band selection for an optical sensor device.

FIG. 11C provides an example side cross-sectional view of an integrated interference filter and plasmonic rejection filter pair with a plasmonic rejection filter disposed either above or below the interference filter. In an example, back-end-of-line (BEOL) metallization (thin film layer 234) is provided on substrate 226 on a semiconductor die. In the example, a plasmonic rejection layer (plasmonic rejection filter 223) can be located on top of the BEOL layer, with an interference filter (spectral filters 222), such as a Fabry-Perot filter disposed atop the plasmonic rejection layer. In an alternative example, an interference filter can be located on top of the BEOL layer, with a plasmonic rejection layer disposed atop the interference filter.

In an example, nanoscale semiconductor material-based filters, such as thin-film quantum dots can be manufactured using narrow bandgap thin-films compatible with conventional semiconductor processing. In an example, thin-film quantum dots of varying size can be used to provide filter responses across a predetermined spectrum, where the granularity and spectrum bandwidth of the thin-film is determined by the number and size of the quantum dots. The quantum dots can be, but are not limited to, either epitaxial quantum dots and/or colloidal quantum dots. Nanoscale semiconductor elements can include one or more of quantum dots, colloidal nanoparticles, CdSe nanocrystals and ZnS nanocrystals, etc. In a specific example of implementation, the nanoscale semiconductor elements can be implemented in different “dot” sizes, where the dot size dictates the wavelength of the spectral response for a given nanoscale filter element. In the example, various dot sizes are distributed on the sensor system to provide a spectrum of a given bandwidth and granularity.

In a specific example of implementation, a sensor system includes a plurality of optical sensors arranged on an integrated circuit, the array of optical sensors having a respective top surface and a plurality of nanoscale semiconductor filters configured to filter light in different wavelength bands on the integrated circuit.

In related example, nanoscale semiconductor materials, such as thin-film quantum dots can be used with interference filters, such as Fabry-Perot filters, to increase the wavelength selectivity of a light filter system. In an example, thin-film quantum dots can be integrated on top of interference filters, where, for example, the quantum dots are “grown” epitaxially and/or deposited in the form of colloidal quantum dots.

In another related example, thin-film quantum dots are used with interference filters in a backside configuration for extended wavelength detection, such as, for example, for short-wave infrared (SWIR) detection. In a specific example of implementation, a sensor system includes a plurality of optical sensors, a plurality of sets of interference filters and a plurality of nanoscale semiconductor filters provisioned on the reverse side of the integrated circuit. In the example, the reverse side of the integrated circuit is opposite a side of the integrated circuit with wiring. In an example, the sensor system comprises a backside illumination image sensor. A back-illuminated sensor, also known as backside illumination (BSI or BI) sensor uses the novel arrangement of the imaging elements on the reverse side of the integrated circuit comprising an image sensor in order to increase the amount of light captured and thereby improve low-light performance. The decreased light capture in a front-side (traditional) sensor is at least partially because the matrix of individual picture elements and its wiring reflect some of the light, and thus the sensor can only receive the remainder of the incoming light, because the reflection reduces the signal that is available to be captured.

In a specific example of implementation, a sensor system includes a plurality of optical sensors and a plurality of sets of interference filters with a plurality of nanoscale semiconductor filters provisioned on the backside of an integrated circuit, where the backside is a surface of an integrated circuit opposite wiring.

In a specific related example, interference filters can be transfer printed from a filter substrate to a substrate that includes light sensing elements (detector substrate). In another related example, Fabry-Perot filters manufactured on a silicon substrate can be transfer printed to a short-wave infrared (SWIR) wavelength detector substrate, such as an InGaAs substrate. In one example, the wafer size of the filter substrate and detector substrate are different, where, for example, a filter substrate can be fabricated using an 8″ wafer while an InGaAs-based detector substrate can be fabricated using a 6″ wafer. In another example, rejection filters are transfer printed on top of interference filters, such as Fabry-Perot filters. In yet another example, micro-optical elements such as lenses, apertures or collimating elements are transfer printed on optical filters.

In yet another example, thin-film quantum dots can be used on wavelength selective mirrors, such as the mirrors of a Bragg mirror (see FIGS. 9A and 9B). In a specific example, the thin-film quantum dots are incorporated as elements of an interference filter, such as a Fabry-Perot filter. In the example, a dielectric mirror, also known as a Bragg mirror, is a mirror composed of multiple thin layers of dielectric material. In a specific example of implementation, A sensor system includes a plurality of optical sensors arranged on an integrated circuit, the plurality of optical sensors having a respective top surface, with a plurality of sets of interference filters having a respective top surface and a respective bottom surface, where each interference filter of the set of filters is configured to pass light in a different wavelength range. In an example, the bottom surface of the plurality of sets of interference filters is located proximal to the top surface of the plurality of optical sensors, with the plurality of interference filters configured to filter light in different wavelength bands. In the example, each interference filter of the plurality of interference filters comprises a plurality of mirrors, wherein at least one mirror of the plurality of mirrors comprises nanoscale semiconductor material. In an example, at least one of the interference filters is a Fabry-Perot filter. In another example, the nanoscale semiconductor material is configured to decrease a wavelength range of at least one interference filter as compared to an interference filter that does not comprise nanoscale semiconductor material.

Referring to FIG. 5a and FIGS. 11A-C, wavelength selectivity using bandpass filters can result in a loss of information in wavelength bands that are being filtered. Said another way, a portion of the information included in an image of an object and/or scene projected on a multi-spectral bandpass filter will be rejected by the bandpass filters when that information is not in the bandpass wavelengths of interest and is therefore lost from the projected image.

In an example, wavelength division multiplexing (WDM), either by spatial division or by time division, can be used to provide wavelength selectivity without the loss of information inherent in bandpass filtering. WDM is used in optical communications to multiplex a number of optical carrier signals onto a single optical fiber by using different wavelengths of light. In an example, WDM provides for combining signals with different wavelengths, such as lasers or LEDs with different central wavelengths (CWLs), using a multiplexer and then sending the signal through the optical fiber. The combined signals can them be separated into wavelengths with a demultiplexer before the signals reach a sensor system.

In a specific example of implementation and operation, a spectral sensor system includes a multiplexer configured to multiplex incident light into a wavelength division multiplexed optical signal and an optical conduit configured to convey the wavelength division multiplexed optical signal. In an example, the sensor system includes a demultiplexer configured to separate the wavelength division multiplexed optical signal into wavelengths and a plurality of optical sensors arranged on an integrated circuit, the plurality of optical sensors having a respective top surface, wherein each optical sensor of the plurality of optical sensors is configured to sense one or more light wavelengths from the demultiplexer and one or more processors, where the one or more processors are adapted to provide a spectral response for the incident light.

In a related example, the demultiplexing is accomplished using one or more micro-grating arrays, where each micro-grating array includes a plurality of diffraction gratings. In an example, a diffraction grating is an optical component with a periodic structure that splits and diffracts light into several beams travelling in different directions. The directions of the beams depend on the spacing of the grating and the wavelength of the light so that the grating acts as the dispersive element. In another specific example of implementation and operation, a sensor system includes a micro-grating array having a respective top surface and a respective bottom surface, where the micro-grating array includes a plurality of diffraction gratings and each diffraction grating of the plurality of diffraction gratings is configured to diffract incident light into a plurality of wavelengths. In an example the sensor system includes a plurality of sets of optical sensors, the plurality of sets of optical sensors having a respective top surface, wherein the top surface of the plurality of sets of optical sensors is proximal to a micro-grating array and where each optical sensor of a set of optical sensors is configured to sense one or more wavelengths dispersed from a diffraction grating of the plurality of diffraction gratings. In another example the micro-grating is replaced by a micro-dispersive optical element, such as a meta material-based dispersive element.

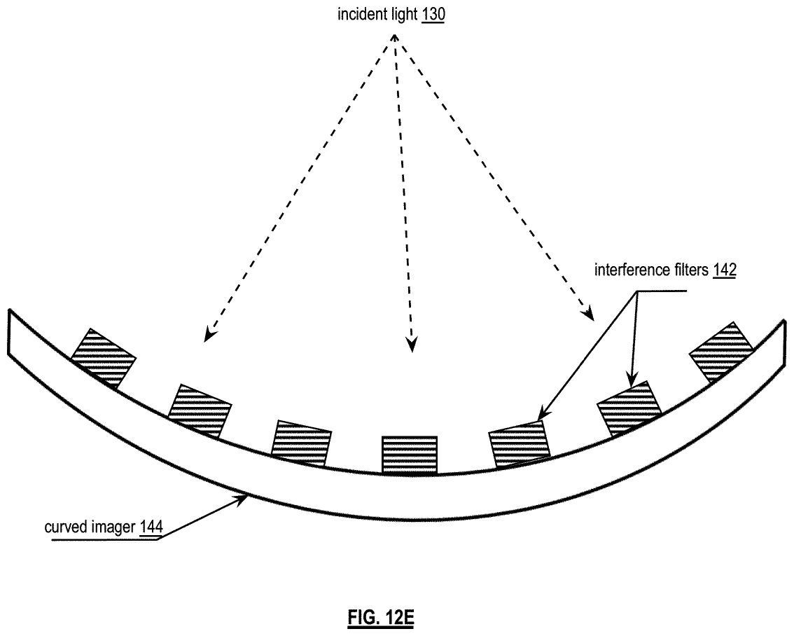

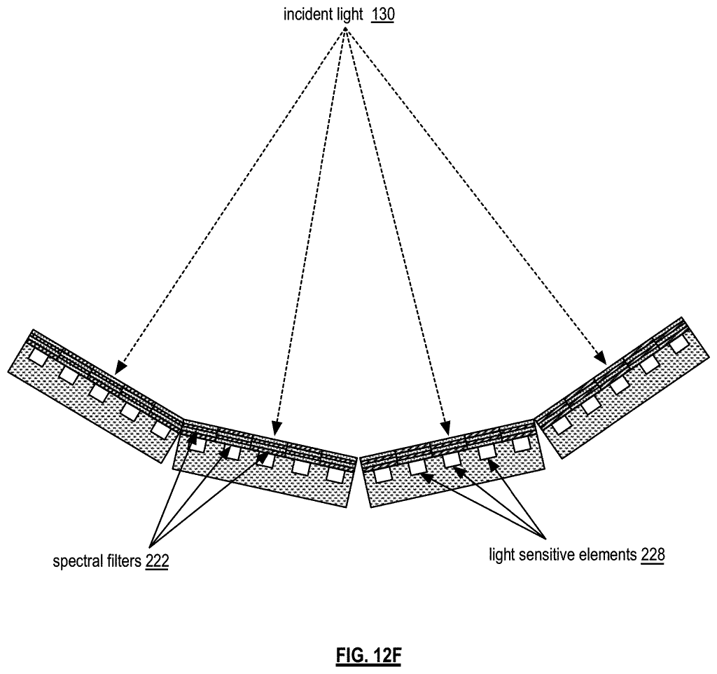

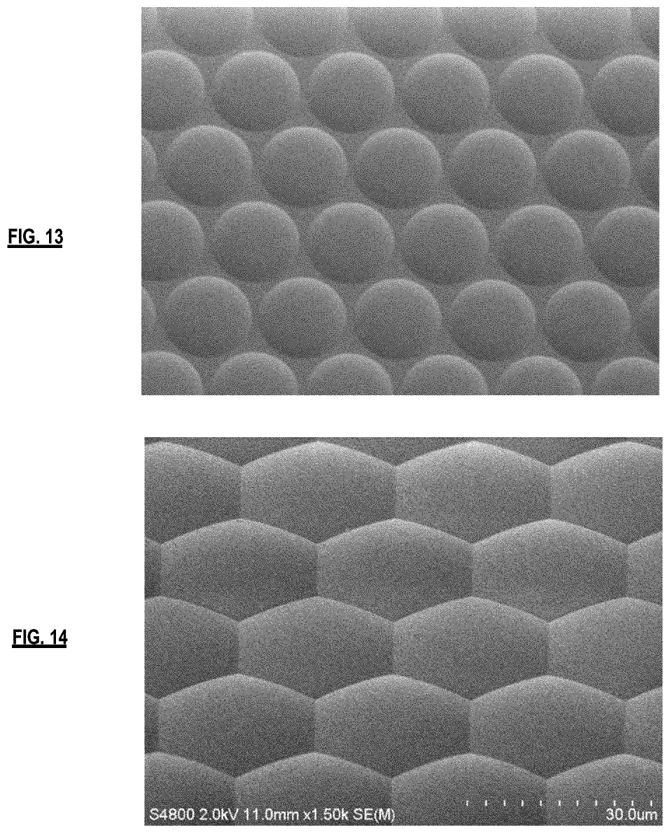

FIG. 12A provides an example side cross-sectional view of an imaging system incorporating a micro-lens array 238 and a micro-grating array 240. The imaging system includes an optical element 236 for projecting a scene or object (such as micro-rainbow array patter 242) on an imager 244, with a micro-lens array 238 located between the optical element 236 and the imager 244. In an example, micro-lens array 238 can comprise a variety of shapes, including, but not limited to gapless lenses, dual face lens and square lenses and can further include lens space light shielding.

Interference-based filters, such as Fabry-Perot filters, are known to be sensitive to the angle of incidence of incoming incident light. In an example, the center wavelength and the width of the spectrum passing through interference-based filters can be strongly dependent on the angle of incidence. In an example, spectral systems incorporating one or more arrays of interference-based filters that receive light from a wide field of view can be particularly sensitive to angle of incidence differences on different regions of the interference-based filter array. In an example, a spectrum sensed over different regions of the interference-based filter array can yield central wavelengths and widths that are undesirable.

FIG. 12B provides a side view of a lens 44 adapted to redirect incident light 130 on an image sensor (not shown). In an example, one or more lenses can be used to narrow the angle of incidence of incoming incident light on an array of interference-based filters. In the example, one or more lenses can be used to redirect incident light rays coming from wide angles in the direction normal to the surface of an image sensor, creating a substantially collimated beam. In a specific example of implementation and operation, referring to FIG. 1, a package 16 having a respective top surface, a respective bottom surface and a respective plurality of side surfaces with the top surface includes a package aperture 12, the top surface, the plurality of side surfaces and the bottom surface forming a cavity. In an example, one or more lenses are configured atop the package aperture 12, where the one or more lenses are adapted to redirect incoming incident light in a direction substantially perpendicular to the top surface of package 16.

In an example, a substrate 26 having a respective bottom surface and a respective top surface is located within the cavity of package 16, the bottom surface of the substrate 26 being coupled to the bottom surface of the package 16 and a plurality of light sensitive elements 28 are located on the top surface of the substrate 26. In the example, a plurality of sets of spectral filters having a respective top surface and a respective bottom surface are located atop the plurality of light sensitive elements 28, where a set of spectral filters of the plurality of sets of spectral filters includes a plurality of spectral filters that are arranged in a pattern such that each spectral filter of the plurality of spectral filters is configured to pass light in a different wavelength range.

FIG. 12C provides a side view of a microstructure array 246 adapted to redirect incident light 130 on an image sensor (not shown). In the example, one or more microstructure arrays can be used to narrow the angle of incidence of incoming light on an array of interference-based filters. In the example, one or more microstructure arrays can be used to redirect incident light rays in a perpendicular direction, creating a substantially collimated beam. redirect the rays. In an example, the microstructure arrays can include one or more of, Fresnel lenses and/or micromirrors. FIG. 12D provides a side view of a micromirror array (micro-mirrors 248) adapted to redirect incident light 130 on an image sensor (not shown). In a specific example of implementation, one or more microstructure arrays can be fabricated using a micro imprint process. In another specific example of implementation, one or more microstructure arrays can be fabricated using a deposition process incorporating reflective coatings.

In a specific example of implementation and operation, referring to FIG. 1, a package 16 having a respective top surface, a respective bottom surface and a respective plurality of side surfaces with the top surface includes a package aperture 12, the top surface, the plurality of side surfaces and the bottom surface forming a cavity. In an example, one or more microstructures are configured atop the package aperture 12, where the microstructures are adapted to redirect incoming incident light in a direction substantially perpendicular to the top surface of package 16.

In an example, a substrate 26 having a respective bottom surface and a respective top surface is located within the cavity of package 16, the bottom surface of the substrate 26 being coupled to the bottom surface of the package 16 and a plurality of light sensitive elements 28 are located on the top surface of the substrate 26. In the example, a plurality of sets of spectral filters are configured as a plurality of sets of optical filters (spectral filter 22) having a respective top surface and a respective bottom surface located atop the plurality of light sensitive elements 28, where a set of spectral filters of the plurality of sets of optical filters includes a plurality of spectral filters that are arranged in a pattern where each spectral filter of the plurality of spectral filters is configured to pass light in a different wavelength range.

FIG. 12E provides a side view of an example imager 144 adapted to provide a curved surface for collecting incident light 130. In an example, an imager comprises a plurality of interference filters 142 fabricated on top of a plurality of image sensors on a substrate, with the substrate being subsequently bent or curved to a predetermined curvature. In the example, the curvature of the substrate is determined based on the range of entry angles for light being collected, such that relatively larger angles of light will have a narrower angle of incidence range on interference-based filters before being collected at the image sensors. In an example, the curved imager substrate can reduce the center wavelength and spectrum width dependency of the imager to larger angles of incidence.

In a specific example of implementation and operation, a sensor system includes a plurality of sets of optical filters, where a set of optical filters of the plurality of sets of optical filters includes a plurality of optical filters that are arranged in a pattern, wherein each optical filter of the plurality of optical filters is configured to pass light in a different wavelength range. The plurality of sets of optical filters are located on top of a plurality of light sensitive elements, where the plurality of sets of light sensitive elements are located on a curved substrate. In a specific related example, the plurality of sets of optical filters and the plurality of light sensitive elements are fabricated on the substrate prior to a curvature being applied to the substrate. In another specific example, each optical filter of the plurality of optical filters includes a plurality of respective sides, and each optical filter is separated on the respective sides from an adjacent optical filter by a air gap.

FIG. 12F provides a side view of another example imager adapted to provide a curved surface for collecting incident light. In an example, an imager comprises a plurality of relatively smaller segments of spectral sensors (spectral filters with light sensitive elements 228), with the surface of each individual segment slightly rotated with respect to the surface of adjacent segments. In an example, the individual segments are configured based on a desired range of entry angles for light (incident light 130) being collected, such that relatively larger angles of light will have a narrower angle of incidence range on interference-based filters before being collected at the image sensors. In an example, the individual segments are fabricated before being placed on a curved substrate or plate, where the substrate or plate is curved to a predetermined curvature. In a related example, the substrate or plate is curved on a single plane. In another example, the substrate or plate is curved on more than a single plane.

In a specific example of implementation and operation, a sensor system includes a plurality of sets of optical filters, where a set of optical filters of the plurality of sets of optical filters includes a plurality of optical filters that are arranged in a pattern, wherein each optical filter of the plurality of optical filters is configured to pass light in a different wavelength range. The plurality of sets of optical filters are located on top of a plurality of light sensitive elements, where the plurality of sets of light sensitive elements are located on a curved substrate. In a specific related example, the plurality of sets of optical filters and the plurality of light sensitive elements are fabricated on the substrate prior to a curvature being applied to the substrate. In another specific example, each optical filter of the plurality of optical filters includes a plurality of respective sides, and each optical filter is separated on the respective sides from an adjacent optical filter by a air gap.

FIG. 13 is a micrograph of an example convex micro-lens, while FIG. 14 is a micrograph of an example concave micro-lens. In an example, a micro-grating array is located between the micro-lens array and the imager. In an example, the micro-grating array functions as a demultiplexer in front of an array of light sensitive elements on the imager. The micro-grating array separates wavelengths coming from an imaged scene and sends each wavelength to a specific light sensitive element.

In a specific example of implementation, a sensor system includes a plurality of sets of optical sensors, the plurality of sets of optical sensors having a respective top surface and a respective bottom surface. The sensor system further includes a micro-grating array having a respective top surface and a respective bottom surface, and a micro-lens array having a respective top surface and a respective bottom surface, where the bottom surface of the micro-grating array is located between the bottom surface of the micro-lens array and the top surface of the plurality of sets of optical sensors. In an example, each optical sensor of a set of optical sensors is configured to sense one or more wavelengths dispersed from a diffraction grating of the plurality of diffraction gratings.

In a specific example, the sensor system also includes a micro-collimator array having a respective top surface and a respective bottom surface, along with an array of absorption filters where the bottom surface of the micro-collimator array is located atop the array of absorption filters. In an alternative example, the sensor system includes a plasmonic-collimator array having a respective top surface and a respective bottom surface and an array of absorption filters, where the bottom surface of the plasmonic-collimator array is located atop the array of absorption filters. In a related example, each plasmonic-collimator of the plasmonic-collimator array comprises a nanostructure configured to couple diverging incoming light into a light beam.

In yet another example, the sensor system includes a plurality of sets of interference filters having a respective top surface and a respective bottom surface, where each interference filter of the set of filters is configured to pass light in a different wavelength range and where the bottom surface of the plurality of sets of interference filters is located on the top surface of the array of optical sensors. In a related example, each interference filter of the set of interference filters is associated with a collimator of a collimator array. In another related example each set of interference filters is associated with one or more diffraction gratings of the micro-grating array. In yet another related example, each interference filter of the set of interference filters is associated with one or more wavelengths of the plurality of wavelengths dispersed by a micro-diffraction grating of the micro-grating array.

In a related example, plasmonic collimators can be used to direct light in a sensor system with integrated filters and the light sensing elements. In an example, plasmonic collimators can be nanostructures, that can couple diverging (off-angle) incoming light into a light beam with a small divergence, effectively collimating the incoming light. Plasmonic collimators can have a small thickness due to its structure and can replace metal-based and lens-based collimators.

In a specific example of operation, a method includes receiving incident light at a micro-lens array, where each lens of the micro-lens array is associated with one or more diffraction gratings of a micro-grating array and where the micro-lens array is proximal to the micro-grating array. The method continues with refracting, by a lens of the micro-lens array, the received incident light into a focused light beam and separating, by a diffraction grating of a micro-grating array, the focused light beam into a plurality of light spectra. The method continues with sampling of each light spectrum of the plurality of light spectra by a set of spectral sensors of the plurality of sets of spectral sensors, where each spectral sensor of the plurality of sets of spectral sensors is spatially separate from every other spectral sensor of the plurality of sets of spectral sensors. In a related example, the incident light is projected on the micro-lens array through one or more optical elements, such as a simple or compound lens.

In an example of implementation and operation, a sensor system can use a demultiplexer to spatially separate wavelengths from an optical fiber. In the example, the demultiplexer separates the different wavelengths transmitted in the optical fiber in close proximity to an integrated filter system, where each wavelength (or wavelength range) is directed to a corresponding filter of an integrated filter system. In an example, an integrated filter system can be coupled to a plurality of optical fibers for providing wavelength separation.

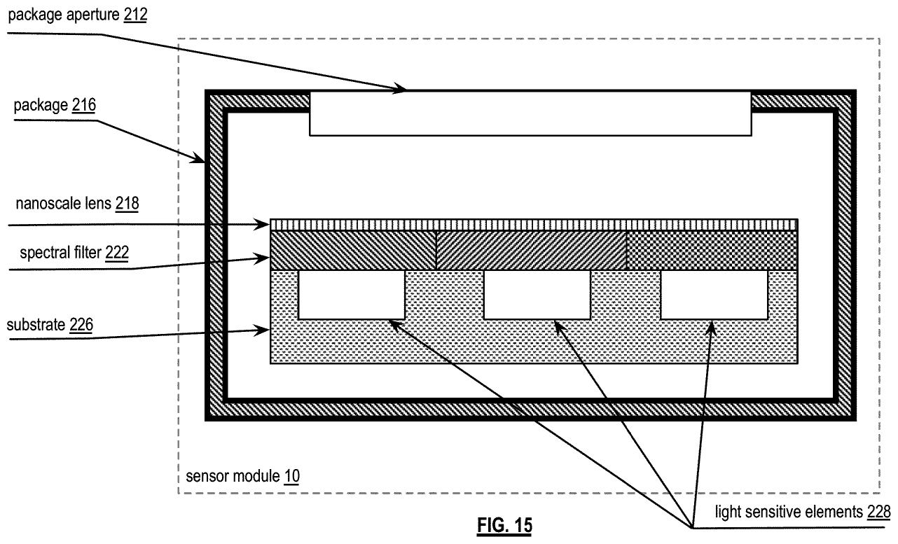

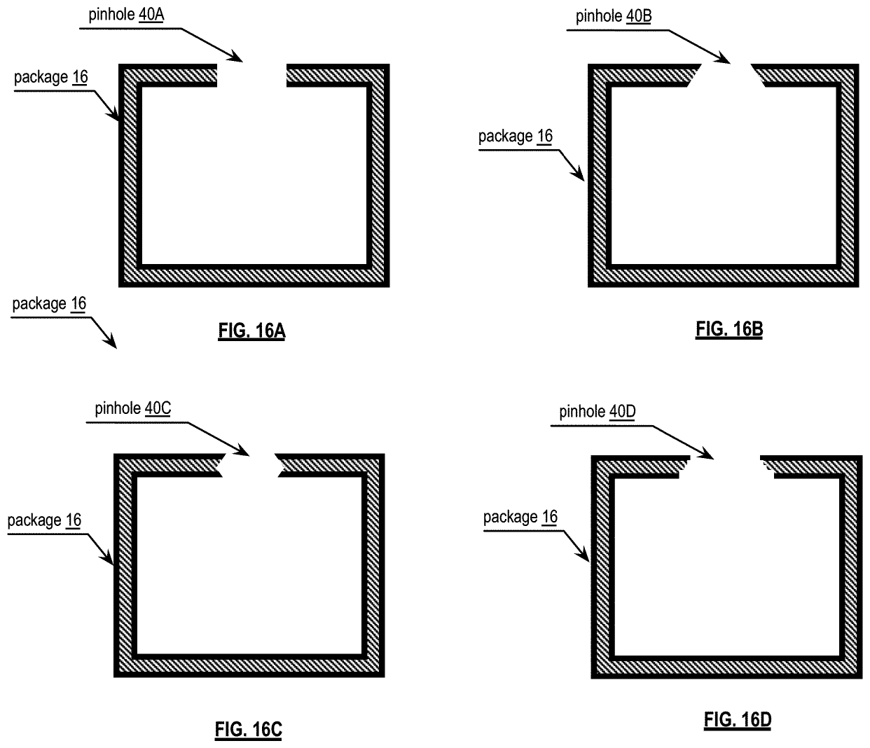

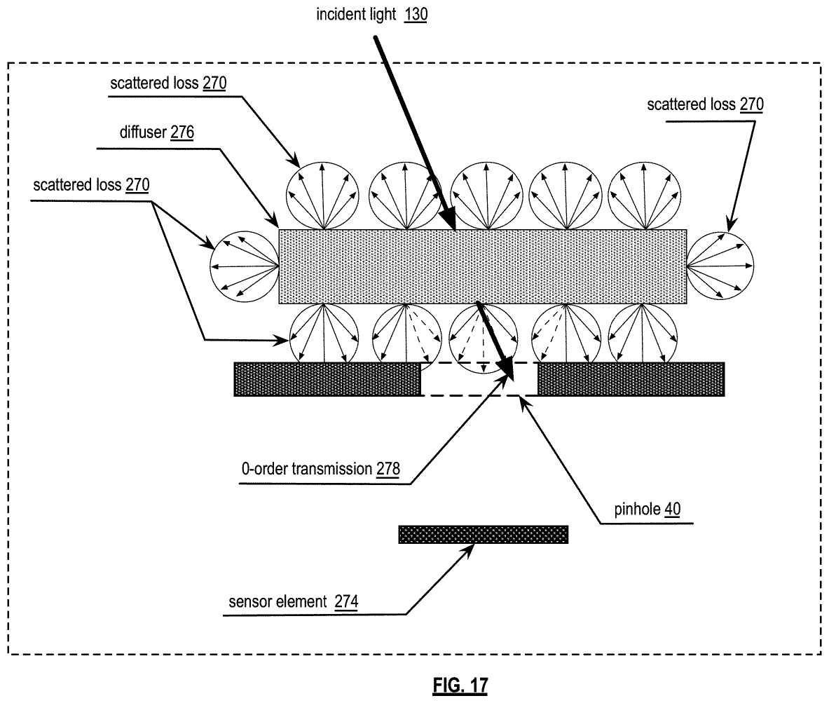

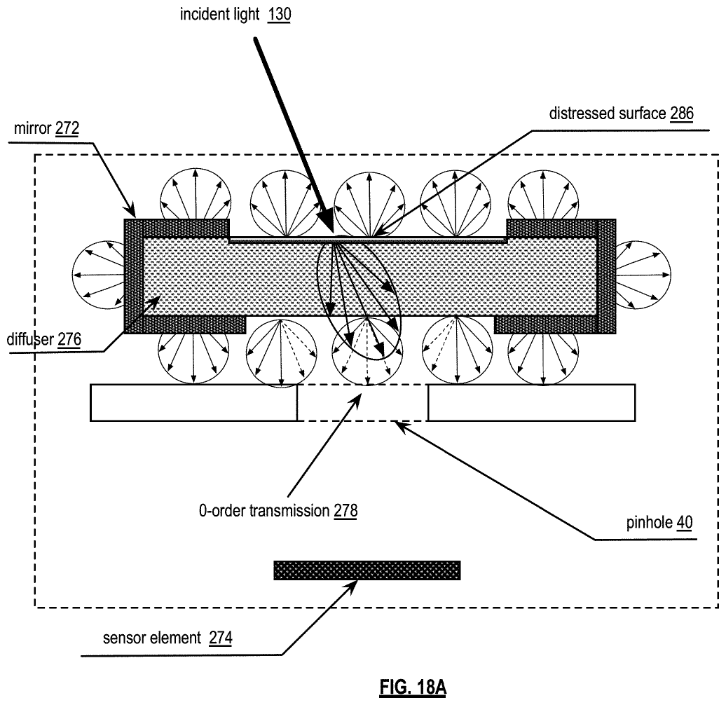

FIG. 15 provides a side cross-sectional view of a sensor module 10 that includes a package 216 incorporating a package aperture 212. Light sensitive elements (sensors) 228 are embedded in a substrate 226. Spectral filter 222 comprises multiple spectral filter elements integrated on light sensor 224. Nanoscale lens 218 is located within the cavity of sensor module 10. In an example, angle-of-incidence devices, such as micro-lenses, light pipes and collimators can be used to improve the performance, such as the quantum efficiency (QE), of a sensor system by controlling the angle-of-incidence of light before it reaches the integrated filters and light sensing elements of the sensor system. When incorporated in packaging structures, such as package 216 of FIG. 15, the thickness of angle-of-incidence devices can result in larger packaging structures. In an example, a nanoscale lens, such as nanoscale lens 218 of FIG. 15, can enable the use of thinner packaging structures.

In a specific example of implementation, A sensor module includes a container having a respective top surface, a respective bottom surface and a respective plurality of side surfaces, where the top surface includes an aperture, the top surface, the plurality of side surfaces and the bottom surface forming a cavity. In the example, a substrate having a respective bottom surface and a respective top surface is located within the cavity, the bottom surface of the substrate being coupled to the interior bottom surface of the container. In an example, a plurality of light sensitive elements are located on the top surface of the substrate, the plurality of sets of optical filters configured as a layer having a respective top surface and a respective bottom surface located atop the plurality of light sensitive elements. In an example, a set of optical filters of the plurality of sets of optical filters includes a plurality of optical filters that are arranged in a pattern, where each optical filter of the plurality of optical filters is configured to pass light in a different wavelength range. In an example, one or more nanoscale lens configured on the top surface of the plurality of sets of optical filters and a cover is located at least partially within the aperture.

In an example, the nanoscale lens is a Fresnel lens and/or a metamaterial lens. In another example, the nanoscale lens is formed by etching the top surface of the plurality of sets of optical filters. In yet another example, the nanoscale lens is etched on the top surface of the plurality of sets of optical filters using one or more of wet etch, DRIE etch or ion milling. In yet another example, the nanoscale lens is molded from plastic and glued or otherwise coupled to another sensor element. In another example, the nanoscale lens is transfer printed from a source substrate to another sensor element, such as the detector substrate.

In an example, micro-lenses, such as the micro-lenses illustrated in FIGS. 13 and 14 are configured as a single layer. In an example, multiple micro-lens layers can be stacked, creating compound micro-optics that can direct light more efficiently to corresponding filters of an integrated filter of the filter system. Example compound micro-optics include telecentric systems and reverse-telecentric systems.

In a specific example of implementation, a sensor system includes a plurality of sets of optical sensors, the plurality of sets of optical sensors having a respective top surface and a respective bottom surface and a first micro-lens array having a respective top surface and a respective bottom surface, where each lens of the first micro-lens array is associated with one or more optical sensors of the plurality of sets of optical sensors. In an example, the bottom surface of the first micro-lens array surface is located on or in close proximity to the top surface of the plurality of sets of optical sensors. In the example, the sensor includes a second micro-lens array having a respective top surface and a respective bottom surface, where each lens of the second micro-lens array is associated with one or more lenses of the first micro-lens array and the bottom surface of the second micro-lens array surface is located on or in close proximity to the top surface of the first micro lens array. In an example, the first micro-lens array and one or more lenses of the second micro-lens combine to form a compound lens. In another example, the first micro-lens array and one or more lenses of the second micro-lens combine to form one or more of a telecentric lens and/or a reverse-telecentric lens.

Referring to FIG. 15, in an example, package aperture 212 can comprise a macro-optical element. Macro-optical elements can be used to guide received light towards micro-optical elements and can be configured to protect the sensor system from external conditions such as dust and/or humidity. Macro-optical elements can include lenses, apertures, filters, polarizers, diffusers, etc. and be configured to be controlled by mechanical and/or electrical systems.

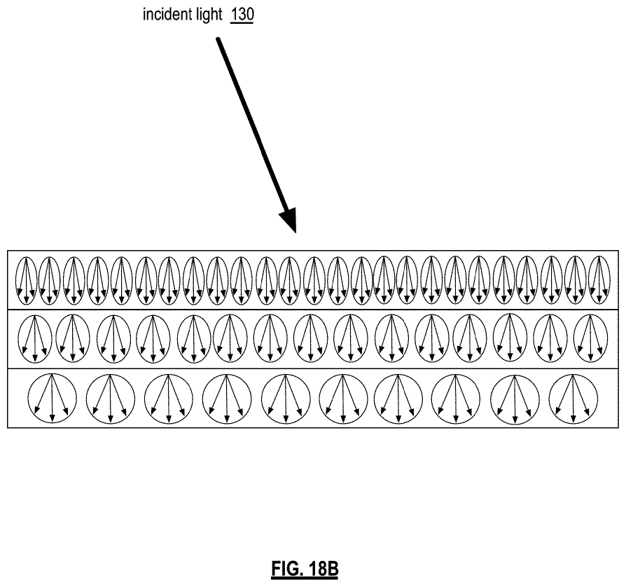

FIGS. 16A-16D illustrates various sidewall profiles for pinole apertures. In an example, a pinhole, such as pinholes 40A-40D from FIGS. 16A-16D can be used to control an angularity-of-incidence of light entering a sensor module, such as package 16, however the thickness of the container walls and the partial reflectivity of the container surface can result in unwanted/parasitic signals reaching the sensor system. In an example, a pinhole can be configured to have sidewalls of a variety of shapes to reduce parasitic signals reaching the sensor system. In a specific example a modified conical shape of the pinhole comprises several stages, with each shape designed to partially control the angularity of light entering a sensor system.

In a specific example of implementation, a sensor module includes a container having a respective top surface, a respective bottom surface and a respective plurality of side surfaces, where the top surface includes an aperture, with the top surface, the plurality of side surfaces and the bottom surface of the container forming a cavity. In the example, a substrate having a respective bottom surface and a respective top surface is located within the cavity, the bottom surface of the substrate being coupled to the interior bottom surface of the container and a plurality of light sensitive elements are located on the top surface of the substrate. In an example, a plurality of sets of optical filters are configured as a layer having a respective top surface and a respective bottom surface located atop the plurality of light sensitive elements, where a set of optical filters of the plurality of sets of optical filters includes a plurality of optical filters that are arranged in a pattern and each optical filter of the plurality of optical filters is configured to pass light in a different wavelength range. In an example, one or more macro-optical elements are located at least partially in the aperture, where each of the macro-optical elements is adapted to control an angle of incidence of light at the top surface of the plurality of sets of optical filters.

In an example, each of the one or more macro-optical elements includes an opening having a sidewall, wherein at least one of the one or more macro-optical elements is adapted to control the angle of incidence of light at the top surface of the plurality of sets of optical filters based at least partially on a sidewall shape. In an example, the sidewall shape is at least one of a cone, an inverted cone, a serration, a series of concentric steps, an hourglass, a stacked cone, a sawtooth, an inverted sawtooth, a hyperboloid, a modified hyperboloid, wherein a top portion of the modified hyperboloid has a smaller aperture than a bottom portion of the hyperboloid and the bottom portion of the hyperboloid further includes a constricting element.

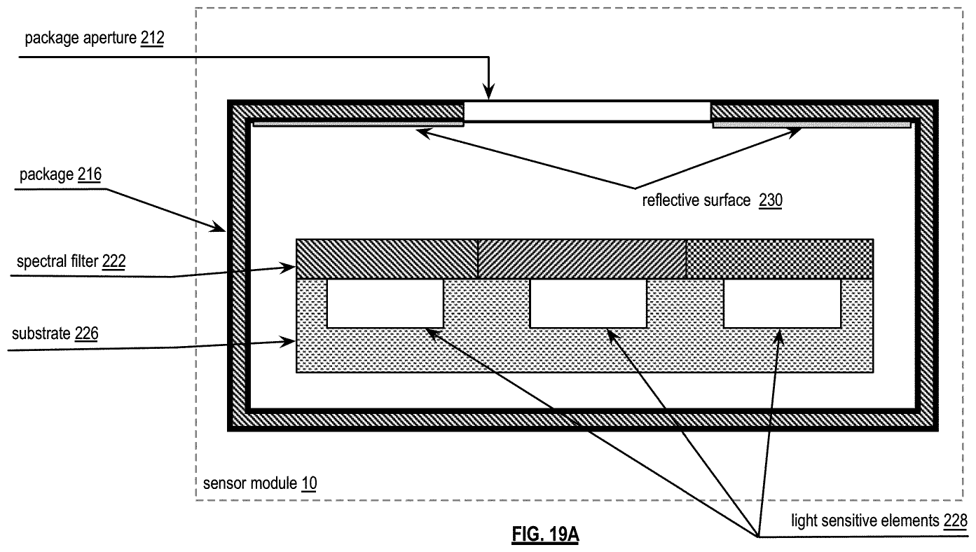

FIG. 17 illustrates scattering from a diffuser (diffuser 276) in a sensor system. Referring again to FIGS. 1 and 15, to protect a sensor system comprising light sensing elements, integrated filters, rejection filters and micro-optical elements, a package can be used to contain the sensor system. In an example referring to FIG. 16, a sensor system package can include one or more apertures through which light from a region of interest passes into the interior of the packaging. In an example, the walls of the container can be opaque to the wavelengths of interest.

In an example, some of the incident light 130 that enters a sensor system package fails to reach the sensor (represented as scattered loss 270), due to the light having the wrong angle-of-incidence or reflecting onto other elements of the system. Some factors preventing light from reaching the light sensitive elements include wrong angles of incidence and reflections on the different elements of the sensor system. In an example, a sensor system can be modified so that light that would otherwise be rejected or impeded from reaching the light sensitive elements is redirected and reaches at least one light sensing element. In an example, a diffuser, such as the diffuser of FIG. 17 can be used to redirect light towards the light sensitive elements, however, as illustrated, diffusers also scatter a considerable amount of light away from the light sensitive elements.

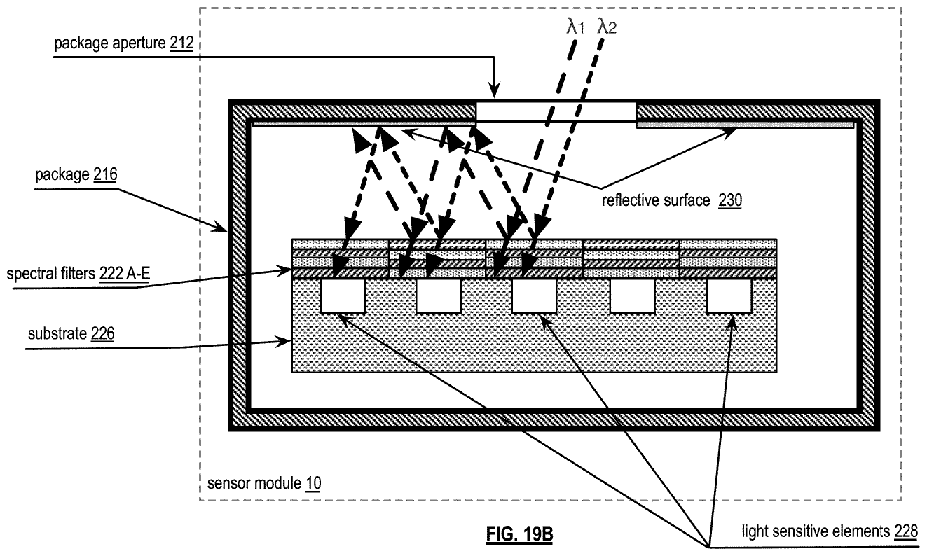

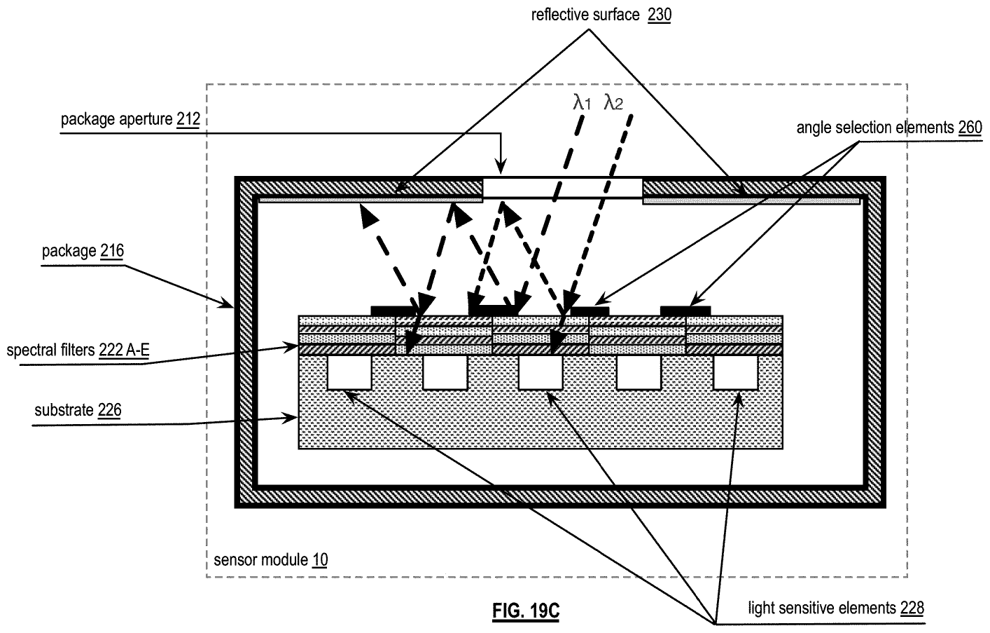

FIG. 18A illustrates a sensor system utilizing a modified diffuser element 276. In an example, the diffuser 276 is partially surrounded by a reflective surface (mirror 272) creating an integrating sphere to redirect light back to the diffuser 276, increasing the probability of the light reaching the light sensitive elements (such as sensor element 274). In a related example, the entrance and/or exit surface of the diffuser is modified with a rough surface (distressed surface 286) to further redirect the light in the direction of sensor element 274. In an example, distressed surface 286 can be created using various methods, such as sandblasting or grinding.

In a specific example of implementation and operation, A sensor system includes a plurality of sets of optical sensors, the plurality of sets of optical sensors having a respective top surface and a respective bottom surface and a plurality of sets of optical filters configured as a layer having a respective top surface and a respective bottom surface located atop the plurality of optical sensors. In the example, a set of optical filters of the plurality of sets of optical filters includes a plurality of optical filters that are arranged in a pattern, where each optical filter of the plurality of optical filters is configured to pass light in a different wavelength range. In an example, a diffusion element having a respective top surface, a respective plurality of side surfaces and a respective bottom surface, is located above the top surface of the plurality of optical filters.

In an example, at least a portion of the plurality of side surfaces of the diffusion element is adapted to reflect light. In an example, at least a portion of the top surface of the diffusion element is adapted to include a rough surface, where the rough surface is a surface that has been treated with a roughening process. In a related example, the roughening process includes at least one of grinding, abrasive blasting, ion milling, atom bombardment or etching. In another example, at least a portion of the top surface of the diffusion element is adapted to reflect light. In yet another example, at least a portion of the bottom surface of the diffusion element is adapted to reflect light. In another example, at least a portion of the bottom surface of the diffusion element has been adapted to include a rough surface, where a rough surface is a surface that has been treated with a roughening process.

Interference-based filters such as Fabry-Perot filters, are configured to reject light of wavelengths outside a predetermined transmission spectrum. Additionally, interference-based filters can fail to transmit some light of wavelengths inside the predetermined transmission spectrum, with a portion of the light being reflected at the surface of the filter(s). In an example, the high reflectivity of the mirrors used in Fabry-Perot filters (such as Bragg mirrors) contribute to the failure to transmit some light of wavelengths inside the predetermined transmission spectrum.

FIG. 18B illustrates a modified diffuser element, such as diffuser 276, comprising multiple diffusion layers. In the example, each layer provides for increased scattering of incident light 130 passing through the diffuser.

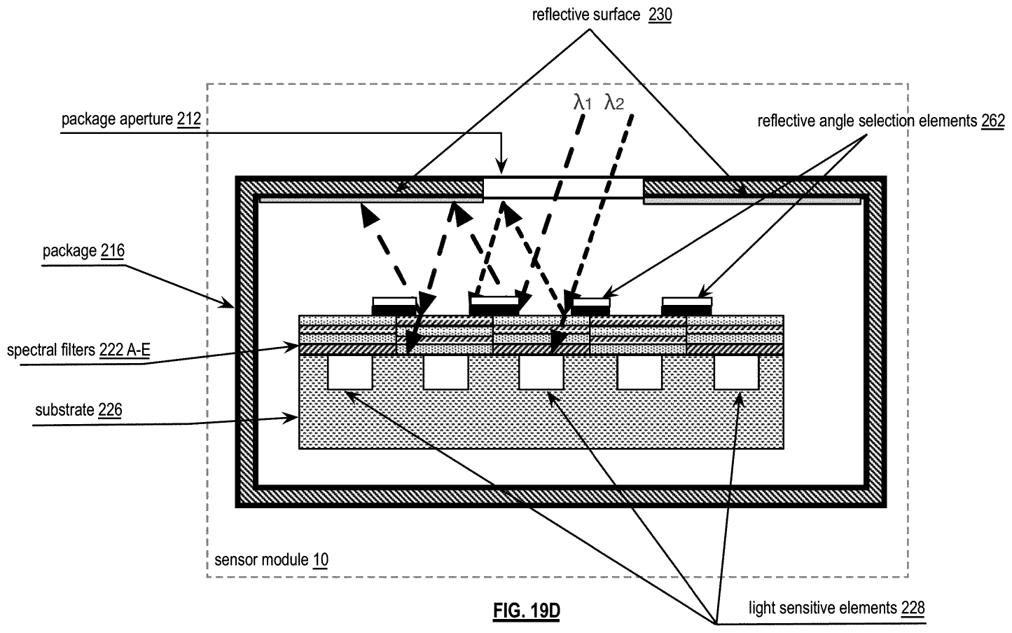

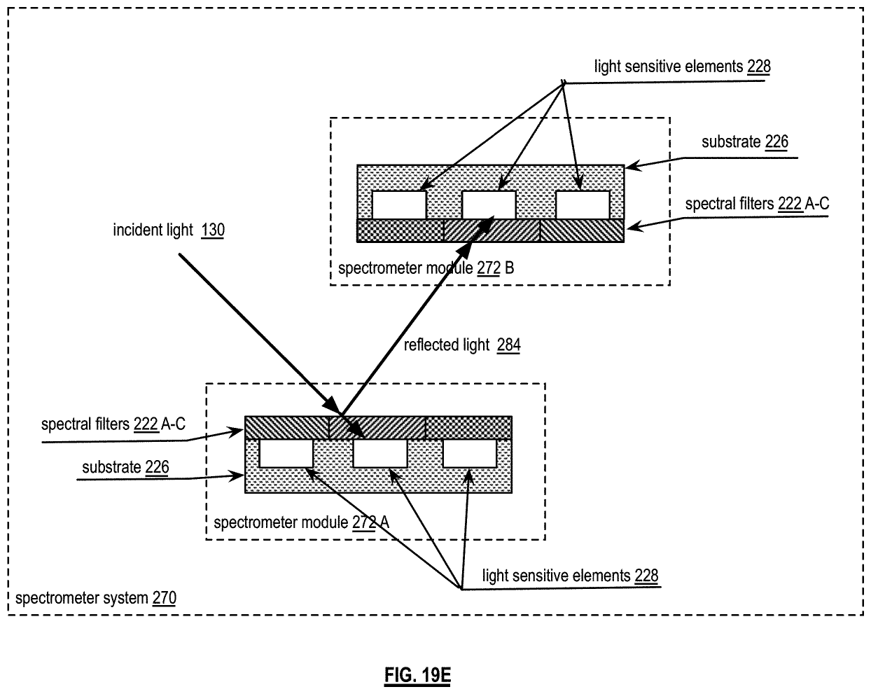

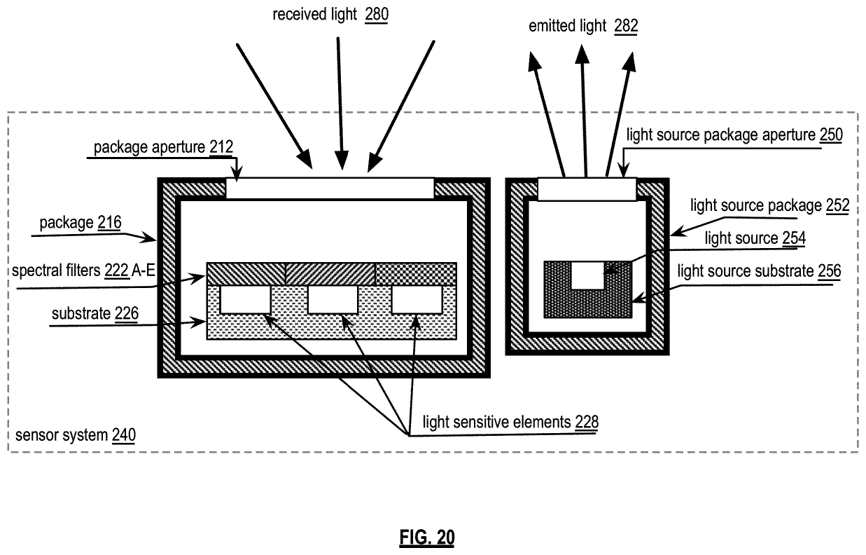

FIG. 19A provides a side cross-sectional view of an example sensor module 10 that includes a sensor system package 216 incorporating reflective surface 230 on interior upper walls of the cavity defined by package 216. In the example, a light trap can be created. In an example, light rejected by the upper surface of spectral filters 222 can be reflected by reflective surface 230 until it reaches a filter of spectral filters 222 with desired/predetermined parameters for transmission. In a specific example of implementation, module 10 includes a package 216 incorporating a package aperture 212. Light sensitive elements (sensors) 228 are embedded in a substrate 226. Spectral filter 222 comprises multiple spectral filter elements overlaying light sensitive elements 228. Reflective surfaces 230 line the upper portion of the inner sidewalls and upper surface of package of the cavity formed by package 216.

In a specific example of implementation, A sensor module includes a container having a respective top surface, a respective bottom surface and a respective plurality of side surfaces, where the top surface includes an aperture and where the top surface, the plurality of side surfaces and the interior bottom surface of the container form a cavity and at least a portion of the interior upper walls of the cavity and/or each side surface of the plurality of side surfaces includes a reflective surface. In the example, a substrate having a respective bottom surface and a respective top surface is located within the cavity, the bottom surface of the substrate being coupled to the bottom surface of the container and a plurality of light sensitive elements located on the top surface of the substrate. In a related example, the side surfaces are adapted to direct incident light to the light sensitive elements.

In an example, a plurality of sets of optical filters configured as a layer having a respective top surface and a respective bottom surface are located atop the plurality of light sensitive elements, with a set of optical filters of the plurality of sets of optical filters including a plurality of optical filters that are arranged in a pattern, where each optical filter of the plurality of optical filters is configured to pass light in a different wavelength range. In another example, the sensor module includes a collimating element configured as a layer having a respective top surface and a respective bottom surface located between the top surface of the plurality of sets of optical filters and the one or more macro-optical elements.

FIG. 19B illustrates two light rays with different central wavelengths λ₁ and λ₂ entering the sensor module 10 defined by the package 216 of FIG. 19A through the package aperture 212. In the example, spectral filter 222 C is designed to transmit only light in wavelength but spectral filter 222 C can also reflect a portion of the light in wavelength λ1. In an example, at least some light at wavelength λ1 and most of the light at wavelength λ2 is rejected by spectral filter 222 C. In the example, a reflective layer (reflective surface 230) on the inner surface of the top of the package 216 redirects the rejected light from spectral filter 222 C to other filters until it encounters either a spectral filter 222 C filter that allows wavelength λ1 to pass or a spectral filter 222 B filter that allows wavelength λ2 to pass.

As discussed with reference to FIGS. 12A through 12F, the transmission of light through interference-based filters is highly dependent on the angle of incidence of incoming light. In an example, angle selective elements can be used on top of the filters to ensure that only light with the right angle of incidence is transmitted. In the case of the light trap described in FIGS. 19A and 19B, a variety of angle selecting elements can be located on top of the array of filters to further control the angle of incidence of incoming light. Example angle selecting elements can be found in FIGS. 12A-12F of U.S. patent application Ser. No. 17/007,254, which is incorporated herein by reference in its entirety.

FIG. 19C provides a side cross-sectional view of another example sensor module 10 that includes a sensor system package 216 incorporating reflective surface 230 on the interior upper walls of the cavity defined by package 216. In the example, each angle selection element 260 of a plurality of angle selective elements is associated with a plurality of spectral filters 222 A-E. In a specific example of implementation, a sensor module includes a container having a respective top surface, a respective bottom surface and a respective plurality of side surfaces, where the top surface includes an aperture and where the top surface, the plurality of side surfaces and the bottom surface of the container form a cavity and at least a portion of the interior top surface and/or each side surface of the plurality of side surfaces includes a reflective surface. In the example, a substrate having a respective bottom surface and a respective top surface is located within the cavity, the bottom surface of the substrate being coupled to the bottom surface of the container and a plurality of light sensitive elements located on the top surface of the substrate.

In an example, a plurality of sets of interference filters configured as a layer having a respective top surface and a respective bottom surface are located atop the plurality of light sensitive elements, with a set of interference filters of the plurality of sets of interference filters including a plurality of interference filters, where each interference filter of the plurality of interference filters is configured to pass light in a different wavelength range. In an example, the sensor module includes a plurality of angle selective elements located at the margin between at least some of the plurality of interference filters, where each of the angle selective elements is configured to block a portion of the light incident on a plurality of interference filters. In an alternative example, a plurality of angle selective elements are configured to block a portion of the light incident on a single interference filters.

In another embodiment, more than one angle selective element is associated with a single filter. In a further embodiment, several angle selective elements are associated with several filters.

FIG. 19D provides a side cross-sectional view of another example sensor module 10 that includes a sensor system package 216 incorporating reflective surface 130 on the interior upper walls of the cavity. In an example, at least a portion of a plurality of reflective angle selection elements 262 are configured to reflect a portion of light incident on spectral filters 222 A-E. In a specific example of implementation, a sensor module includes a container having a respective top surface, a respective bottom surface and a respective plurality of side surfaces, where the top surface includes an aperture and where the top surface, the plurality of side surfaces and the bottom surface of the container form a cavity and at least a portion of the interior top surface and/or each side surface of the plurality of side surfaces includes a reflective surface. In the example, a substrate having a respective bottom surface and a respective top surface is located within the cavity, the bottom surface of the substrate being coupled to the bottom surface of the container and a plurality of light sensitive elements located on the top surface of the substrate.

In an example, a plurality of sets of interference filters configured as a layer having a respective top surface and a respective bottom surface are located atop the plurality of light sensitive elements, with a set of interference filters of the plurality of sets of interference filters including a plurality of interference filters, where each interference filter of the plurality of interference filters is configured to pass light in a different wavelength range. In an example, the sensor module includes a plurality of angle selective elements located at the margin between at least some of the plurality of interference filters, where each of the angle selective elements is configured to reflect a portion of the light incident on a plurality of interference filters. In an alternative example, a plurality of angle selective elements are configured to reflect a portion of the light incident on a single interference filters. In an example of implementation, the fabrication of reflective surfaces on the interior upper walls of the cavity and/or the angle selective elements is done using a deposition process such as metal evaporation, atomic layer deposition, plasma enhanced deposition or any other suitable technique.

FIG. 19E provides a side cross-sectional view of an example sensor system 270 that includes multiple sensor modules (such as spectrometer module 272A and spectrometer module 272B). As discussed with reference to FIGS. 19A-19D, spectral modules are not able to sense all of the incoming light incident on a given spectral module. In an example, incident light can be absorbed by spectral module elements without being transformed into an electric signal, with a portion of the incoming light being reflected (reflected light 284) at the surface of the spectral module (such as spectrometer module 272A). In an example, the wavelengths outside the transmission range of interference-based filters, such as Fabry-Perot filters, are reflected away from the light sensors and, in an example, can be collected at another spectrometer module (such as spectrometer module 272B) oriented to collect the reflected light.

In a specific example of implementation, a sensor system includes a container having a respective top surface, a respective bottom surface and a respective plurality of side surfaces, where the top surface includes an opening and where the top surface, the plurality of side surfaces and the bottom surface of the container form a cavity. In the example, a first sensor module having a respective bottom surface and a respective top surface is located within the cavity, the bottom surface of the substrate being coupled to the interior bottom surface of the container. In an example of implementation, a second sensor module having a respective bottom surface and a respective top surface is located within the cavity, the bottom surface of the second sensor module being coupled to the interior top surface of the container, such that the first sensor module and the second sensor module are offset from each other relative to the opening of the sensor system.

In an example, each of the first and second sensor modules includes a plurality of sets of interference filters configured as a layer having a respective top surface and a respective bottom surface located atop the plurality of light sensitive elements, with a set of interference filters of the plurality of sets of interference filters including a plurality of interference filters, where each interference filter of the plurality of interference filters is configured to pass light in a different wavelength range. In a specific example of implementation, the first sensor module and the second sensor module are offset from each other relative to the opening of the sensor system, so that at least a portion of incoming light passing through the opening is reflected to the top surface of the second module. In another example, the sensor system of FIG. 19E includes a plurality of sensor modules configured to reflect and/or receive reflected light from other sensor modules of the plurality of sensor modules.

In another example (not shown) buried light sensors (pixels) can be configured to sense light that penetrates a sensor substrate without being detected by light sensors associated with one or more interference-based filters. In an example, buried light sensors capture more light than would otherwise be detected. In an example, different light wavelengths penetrate to different depths in a given substrate, thus, buried light sensors can be placed at different predetermined depths in the substrate in order to increase the detection of specific desired wavelengths.

The dynamic range of a particular light sensor can be considered to represent the minimum and maximum signal the light sensor can detect. In an example, high dynamic range (HDR) is desirable because a same light sensor can detect relatively weak and relatively strong signals. In a specific related example, the dynamic range of a semiconductor-based light sensor, such as a photodiode, can be increased by varying an applied bias to the photodiode. In an example, changing the bias can modulate the sensitivity of the light sensor such that higher sensitivity is obtained with larger bias, allowing relatively weaker signals to be detected. Conversely, lower sensitivity is achieved by using a lower bias, with the result that relatively stronger signals can be detected without saturating the photodiode. In a specific example implementation, a bias changing method can be used to enable a given spectral sensor to detect spectral channels with intensities ranging from very weak to very strong. In an example, the change in bias can induce a non-linear response for a given light sensors that can be compensated for during calibration of the light sensors and/or sensor system.

In another example of implementation and operation, dynamic range can be increased by varying an integration period for a given light sensor. In an example, longer integration times provide for detection of relatively weaker signals and shorter integration times prevent saturation from strong signals. In a specific example, the integration can be varied for each light sensor of a plurality of light sensors or it can be varied for an array of light sensors.

In another example of implementation and operation, dynamic range can be increased by using single-photon avalanche diodes (SPADS) in combination with integrated interference-base filters, such as Fabry-Perot filters. In the example, SPADS can be used to detect signals representative of relatively weaker light signals. In a related example, SPADS can be located in close proximity to traditional light sensors, such as photodiodes, where the SPADS can directly collect input light coming from a scene and/or collect rejected light from associated interference-based filters.

FIG. 20 illustrates a sensor system combining a light detection system and a light source. In the example, the sensor system 240 includes a package 216 with a package aperture 212 housing a light detection system that comprises light sensitive elements (sensors) 228 embedded in a substrate 226. Package 216 includes spectral filter 222, which comprises multiple spectral filter elements overlaying light sensitive elements 228. Sensor system 240 includes a light source package 252 with a light source package aperture 250 housing one or more light sources 254 configured on a light source substrate 256. In an example, light source 254 can be adapted to illuminate a region of interest, such as a scene or object of interest, with a spectrum of light (emitted light 282) so that light sensitive elements 228 can detect changes in the spectrum of light resulting (received light 280) from interactions with the region of interest.

In an example, light source 254 provides substantially all of the light illuminating the region of interest. In an alternate example, the light illuminating the region of interest is a combination of light source 254 with other light sources, such as other artificial light and/or natural light. In another example, light source 254 can be a single emission element, such as an light emitting diode (LED) or a laser diode. In an alternate example, light source 254 can comprise multiple elements, such as an array of LEDs, or multiple laser diodes. In yet another example, light source 254 can comprise multiple elements, each configured to emit light in different wavelength bands.

In another example, light source 254 can provide substantially white light, where white light is light containing substantially all the wavelengths of the visible spectrum. In yet another example, light source 254 can be limited to provide light in discreet wavelength bands and in a related example, light source 254 the discreet wavelength bands can be controlled independently as to intensity and/or initiation. In a related example, the emission spectrum of light source 254 can be calibrated and/or controlled over time and/or intensity. In an example of implementation and operation, the light detection system of FIG. 20 can be used to calibrate the output of light source 254.

In a specific example, light source 254 is a phosphor LED. In another example, light source package aperture 250 is covered with a bandpass filter, such that desired LED light is passed, and undesirable light is rejected. In an example, the undesirable light includes wavelengths in the excitation bands of a phosphor LED, such as, for example wavelengths in the range of 450 nm. In an example, a bandpass filter covering light source package aperture 250 is a reflection filter configured to reflect light back into a sensor package or container. In a related example, reflected light energy is added to the direct output of a phosphor type LED, such that the phosphor-type LED achieves better efficiency and provides additional photons in a target range of operation. In yet another example, the light source 254 source is covered with an element configured to provide light confinement, such as, for example, a lens.

In a specific related example, wavelength division multiplexing (WDM) can be used to control the emission spectrum of light source 254, where WDM can be performed in the time domain, the spatial domain or in a combination of both. In an example, a light detection system, such as the light detection system of FIG. 20, can be used to obtain a spectral image of a scene or object by controlling when a specific wavelength or wavelength band is illuminating a specific portion of the scene or object. In an example, the light detection system can be spectral system or, in another example, the light detection system can be a non-spectral system, where a spectral system is a system that extracts spectral information from a region of interest.

In an example, the light source 254 can be paired with the light detection system as part of a feedback mechanism for calibrating and/or controlling the light detection. In another example, the light detection system can be paired with the light source 254 as part of a feedback mechanism for calibrating and/or controlling the light source 254. In a specific example, a feedback mechanism can be used to provide a single calibration sequence at startup of a sensor system, such as sensor system 240. In another example, a feedback mechanism can be used to provide calibration of a sensor system according to a duty cycle. In a specific example, the feedback mechanism can utilize an electronic or mechanical shutter for light source 254.

In a specific example of operation, a method for controlling a light source begins with energizing a light source to output a plurality of wavelengths of light and continues with wavelength division multiplexing (WDM) the plurality of wavelengths of light to produce wavelength division multiplexed light. In an example, the WDM is executed in the time domain, and in another example, the WDM is executed in the spatial domain. In yet another example, the WDM is executed in both a spatial domain and a time domain. The method then continues with illuminating one or more objects using the wavelength division multiplexed light and detecting the resultant light from the one or more objects and using the detected light from the one or more objects to produce a spectral image of the one or more objects. In an example, a portion of the one or more objects is illuminated with a specific wavelength of the plurality of wavelengths of light during a predetermined time period. Finally, the method continues by modifying the light source in response to the detected light from the one or more objects.

FIG. 21 illustrates the use of a micro-grating array 302 to produce a matrix of spectral patterns (micro-rainbow pattern 304) for projection on a scene. In the example, an illumination device (light emitter 300) is configured to emit white light and a micro-grating array 302 is configured to generate a micro-rainbow pattern 304 that can be projected on a scene or object using optical element 306. In an example, the micro-grating array 302 demultiplexes white light from light emitter 300 to produce the micro-rainbow pattern 304. In an alternative example, wavelength division multiplexing (WDM) is used to generate the light with wavelengths spatially distributed in a desired pattern.

In a specific example of implementation, a method begins with energizing a light source to output a plurality of wavelengths of light and continues with wavelength division multiplexing (WDM) the plurality of wavelengths of light to produce a micro-rainbow pattern. In an alternative example, a micro-grating array is used instead of WDM to produce a micro-rainbow pattern. The method then continues with illuminating one or more objects using the wavelength division multiplexed light and detecting the resultant light from the one or more objects and using the detected light from the one or more objects to produce a spectral image of the one or more objects. In an example, a portion of the one or more objects is illuminated with a plurality of wavelengths, that combine to produce a predetermined pattern of wavelengths.

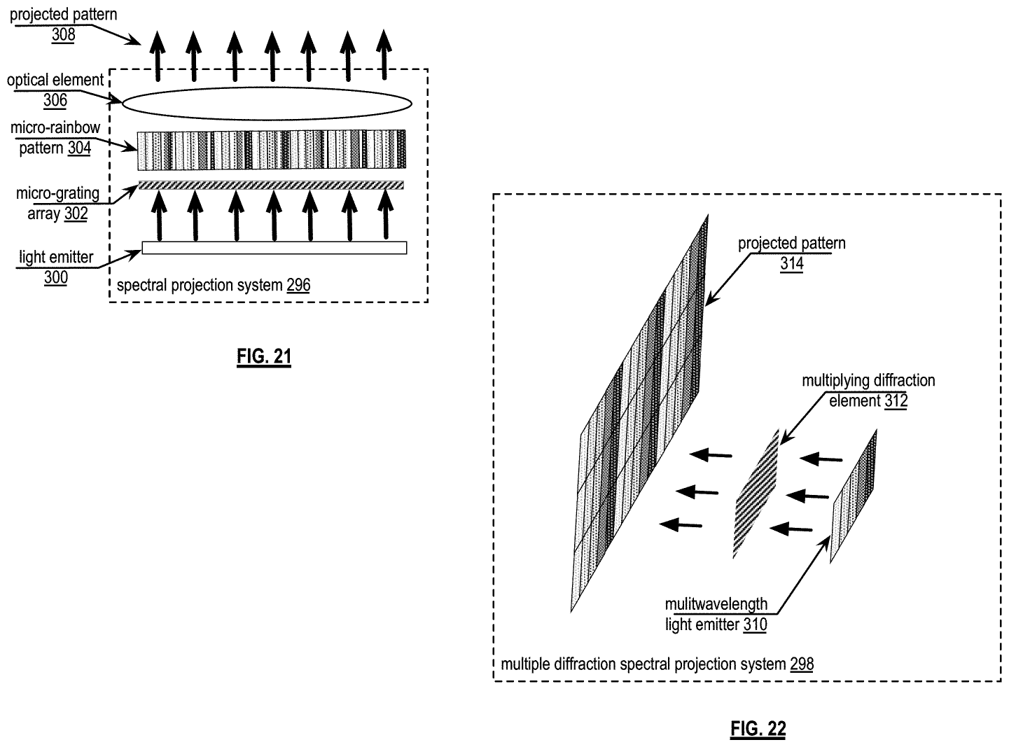

FIG. 22 illustrates the use of a diffractive element to produce a matrix of spectral patterns for projection on a scene. In the example, an illumination device includes an array of light sources that are configured together (multiwavelength light emitter 310) to emit at different wavelengths to output a spectral pattern (projected pattern 314). In an example, a diffractive element (multiplying diffraction element 312) is used to multiply the spectral pattern from multiwavelength light emitter 310 to project projected pattern 314. In a specific example of implementation, a method begins with energizing an array of light sources to output a plurality of wavelengths of light and continues with using a diffractive element to multiply the spectral pattern to project a matrix of spectral patterns.

In another example, a mechanical element is used to scan all or a portion of a scene or object with one or more spectral pattern. In the example, the mechanical scanning enables the illumination of all the spatial points of a scene or object (or portion thereof) with different wavelengths of an illumination device.

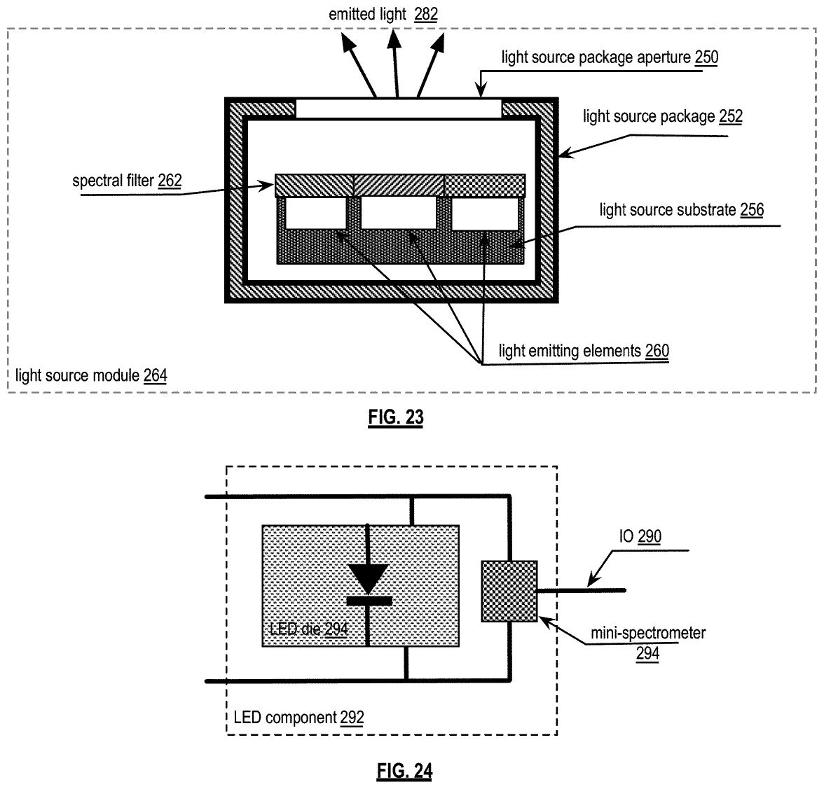

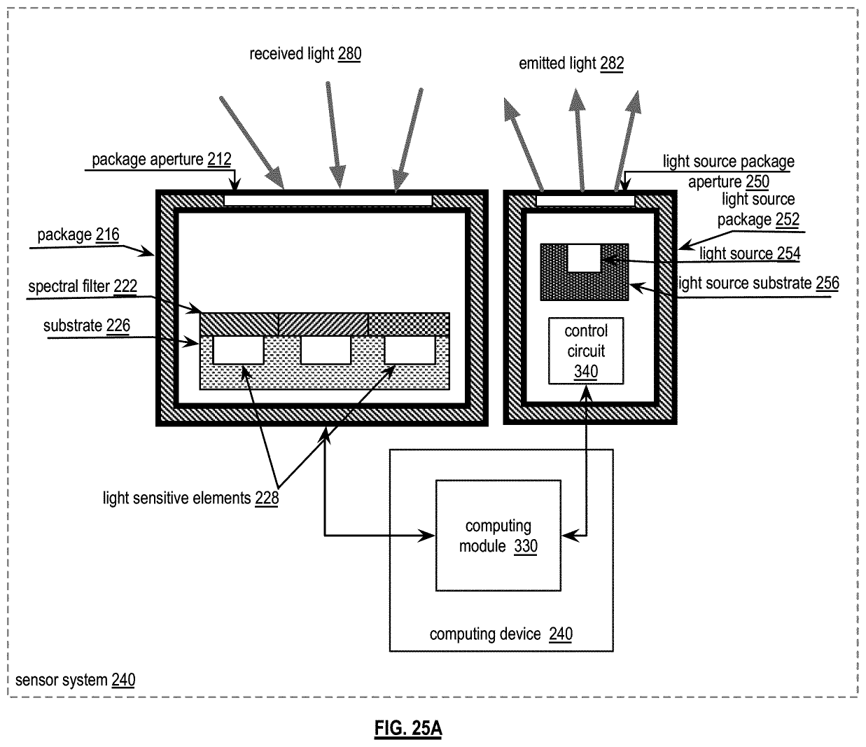

FIG. 23 is a cross section view of an example light source module 264. Light source module 264 includes a light source package 252 with a light source package aperture 250 housing light emitting elements 260 configured on a light source substrate 256. In an example, an array of light filters (spectral filter 262) is used to demultiplex the output of light emitting elements 260 into a spectral pattern. In an example, light emitting elements 260 can be one or more of a plurality of light emitting elements such as light emitting diodes (LEDs), micro-LEDS, nano-LEDS and micro-laser arrays. In an example, each filter in the array of filters can be associated with one or more light emitting elements of the plurality of light emitting elements. In another example, light emitting elements 260 are further configured to provide uniform light to illuminate a scene or object. In another example, light emitting elements 260 are further configured in a mosaic pattern. In yet another example, the light emitting elements 260 comprise one or more of red, green blue (RGB) LEDs or RGB lasers arranged in a mosaic pattern.

In a specific example of implementation, a light source module includes a light source with a respective top surface and a respective bottom surface. In an example, a plurality of sets of optical filters is configured as a layer having a respective top surface and a respective bottom surface located atop the light source, where a set of optical filters of the plurality of sets of optical filters includes a plurality of optical filters that are arranged in a pattern, where each optical filter of the plurality of optical filters is configured to pass light in a different wavelength range. In an example, the light source comprises a plurality of light emitting elements. In another example, each filter of the set of optical filters of the plurality of sets of optical filters is associated with one or more light emitting elements of the light source. In yet another related example, the plurality of sets of optical filters is integrated onto the top surface of the light source.

In an example, the light source comprises a plurality of sets of light emitting elements, where each set of light emitting elements includes a plurality of light emitting elements. In another example, the light emitting elements are selected from a group consisting of light emitting diodes (LEDs), micro-LEDs, plasmonic nano-lasers and nano-LEDs, where different sets of light emitting elements produce light in different spectral bandwidths. In another example, the light emitting elements comprise a plurality of semiconductor layers on a semiconductor substrate. In a specific example, the plurality of sets of light emitting elements can be time-multiplexed, such that certain sets of the plurality of sets of light emitting elements are active during a portion of a time period. In an example, by making different sets of light emitting elements active in a sequence during a time period a region of interest, such as a scene or object can be illuminated with different wavelengths during the time period, effectively producing a spectral sweep scan of the region of interest.

In a specific example of implementation and operation, a light source module includes a light source comprises a plurality of sets of light emitting elements, where each set of light emitting elements includes a plurality of light emitting elements, the light source having a respective top surface and a respective bottom surface. In an example, each light emitting element of the plurality of light emitting elements is configured to emit light according to a timing sequence. In another example, the light emitting elements of the plurality of light emitting elements together are configured to provide a time-sequence of spectra illuminating at least a portion of a region of interest.

FIG. 24 illustrates a light source incorporating a spectrometer with a light emitting element. In the example, a spectrometer (mini-spectrometer 294) is integrated with a light emitting diode (LED) component 292 and is configured to monitor the output of a LED in LED die 294 and output a signal, such as on IO 290. In an example, the spectrometer is configured to transmit information indicating LED performance over the anode or cathode connection to the LED using a 1-wire protocol. In an example, the information can indicate one or more of current central wavelength (CWL), current spectral components and profile for the LED. In a specific example, of implementation and operation, a light source module includes a spectrometer element configured to separate and measure spectral components of the light source. In an example, the spectrometer element can be integrated in the light source substrate, such as the light source substrate 256 from FIG. 23. In another example, a light source module can include a plurality of spectrometer elements, where each spectrometer element of the plurality of spectrometer elements is associated with a light emitting element of the light source.

In an example, the spectral components can be used to detect changes in intensity and/or spectrum of the light source over time. In an example, the changes in intensity and/or spectrum of the light source over time can indicate temperature variations in the light source itself or in the module, along with an indication of aging of the light source. In a specific example, the detected changes can be transmitted directly or, in another example, the light source itself can indicate the detected changes by emitting light in predetermined patterns of pulses and/or flashes. In an alternative example, the detected changes can be transmitted using a calibration feedback mechanism to a sensor module. In a specific example of implementation and operation, a spectrometer is integrated with one or more light emitting diode (LED) components of a liquid crystal display (LCD). In the example, the spectrometer can be used to monitor the performance of the LEDs providing back-lighting for the LCD, so that spectral changes and/or intensity changes can be corrected, or simply to inform a user that the LCD performance is degraded.

Referring again to FIG. 23, in an example implementation, light emitting elements 260 can include light emitting diodes (LEDS) and/or lasers emitting in the infrared (IR), near-infrared (NIR), visible and ultraviolet (UV) wavelengths. In an alternative example, light emitting elements 260 can include one or more broadband LEDs, where the broadband LEDS are adapted to have increased efficiency based on the materials, structure or implementation of the broadband LED. Referring once again to FIG. 23, light source module 264 includes a light source package 252 with a light source package aperture 250 housing light emitting elements 260 configured on a light source substrate 256. In a specific example, light source module 264 can include one or more polarizing elements in the path of light emitted by light emitting elements 260. In an example, the polarizing elements can be one or more of polarizers, quarter-wave plates, half-wave plates or combinations thereof. In an example, the polarizing elements can be located within the cavity formed by light source package 252. In another example, the polarizing elements can be located at least partially within light source package aperture 250. In yet another example, the polarizing elements can be located in the light path of light emitting element outside light source package 252.

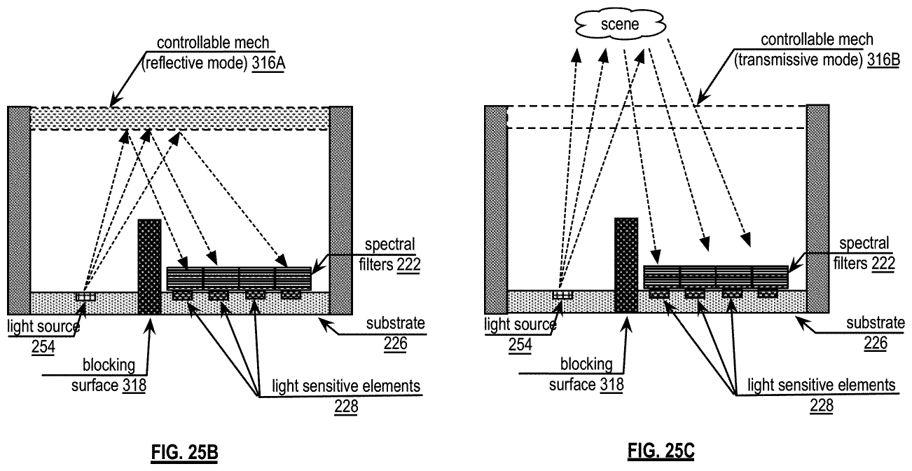

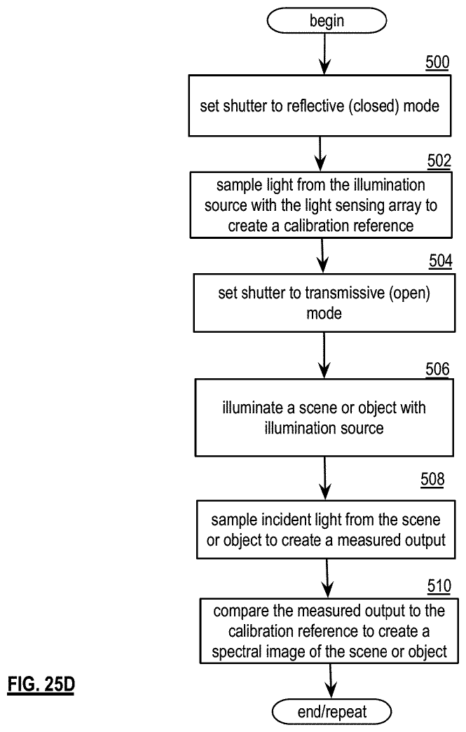

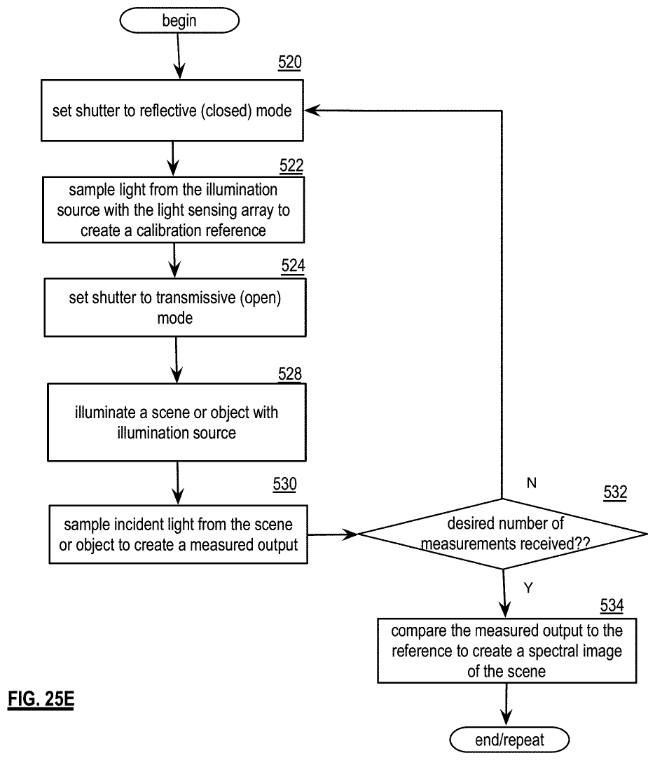

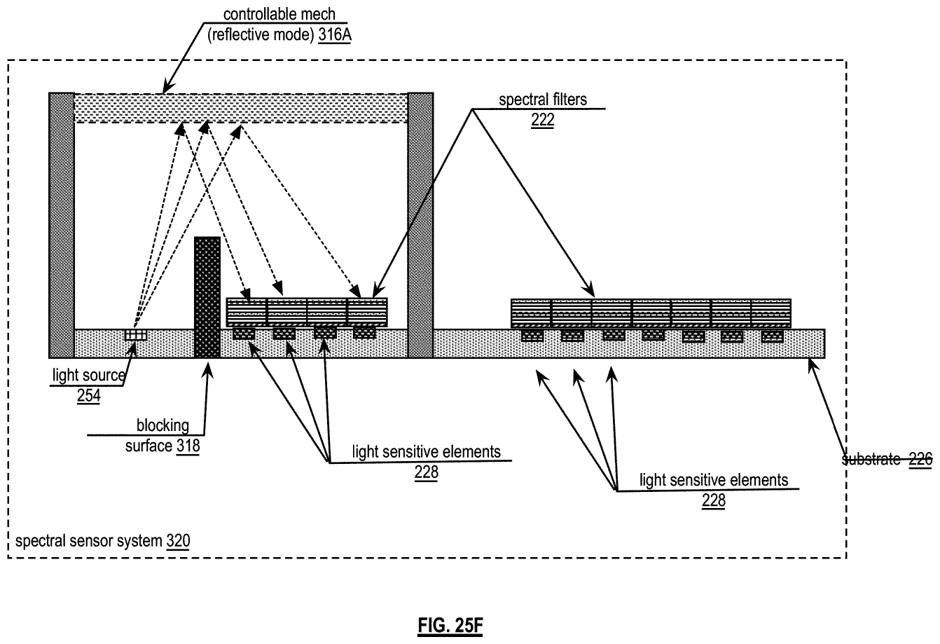

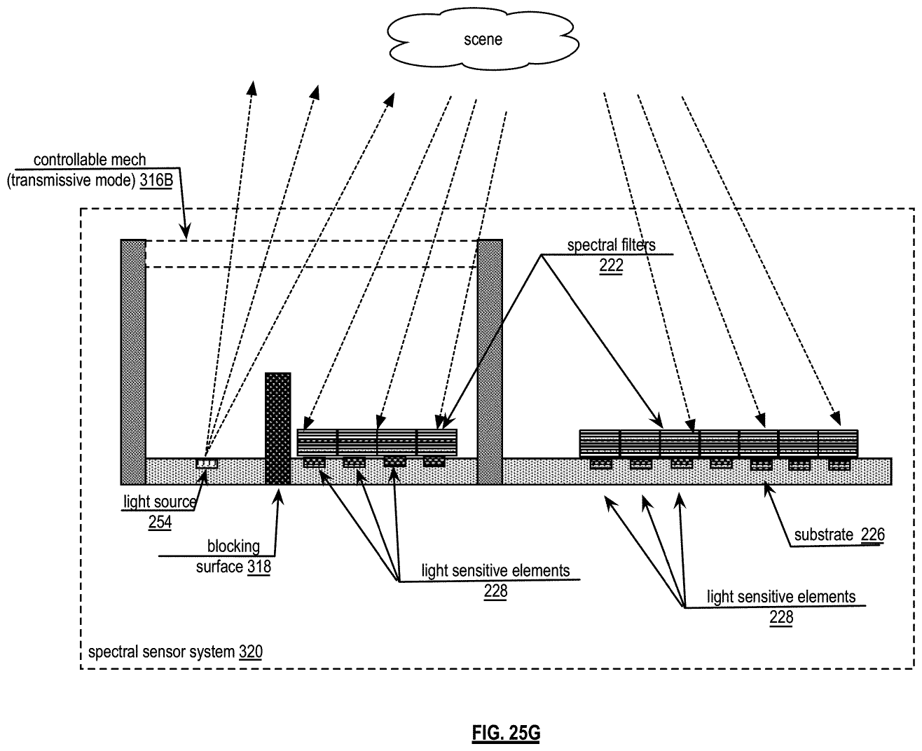

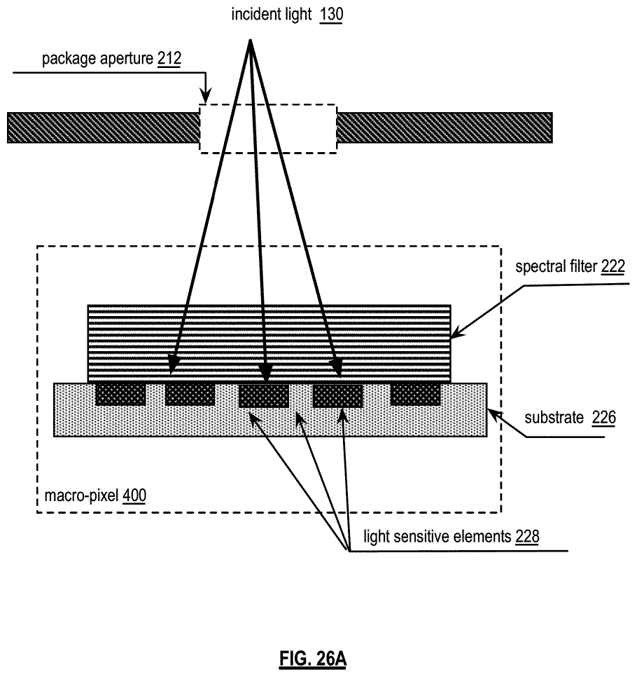

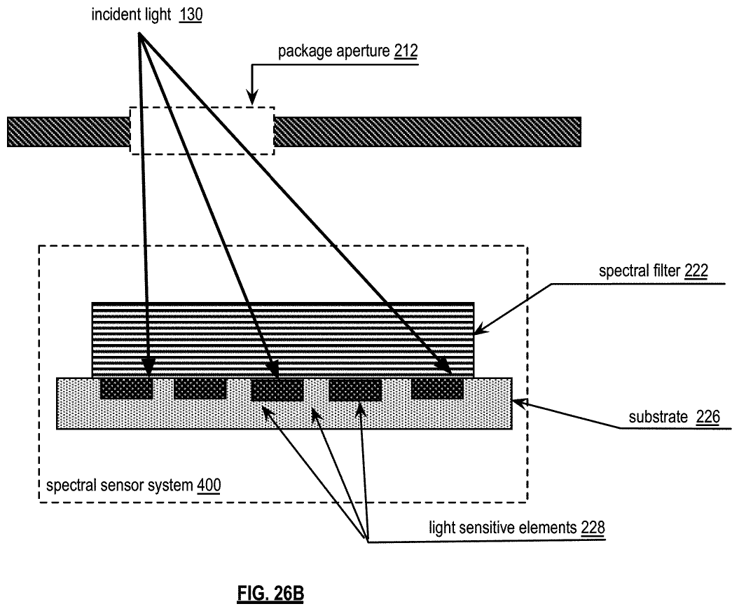

FIG. 25A illustrates another sensor system combining a light detection system and a light source. In the example, the sensor system 240 includes a package 216 with a package aperture 212 housing a light detection system that comprises light sensitive elements (sensors) 228 embedded in a substrate 226. Package 216 includes spectral filter 222, which comprises multiple spectral filter elements overlaying light sensitive elements 228. Sensor system 240 includes a light source package 252 with a light source package aperture 250 housing one or more light sources 254 configured on a light source substrate 256. In an example, light source 254 can be adapted to illuminate a region of interest, such as a scene or object of interest, with a spectrum of light (emitted light 282), so that light sensitive elements 228 can detect changes in the spectrum of light (received light 280) resulting from interactions with the region of interest.

In an example, light source 254 provides modulated illumination controlled by control circuit 340. In an example, light is collected at light sensitive elements 228 and is output either directly or as a signal representative of a spectral response to computing module 330 of computing device 240. In an example, light source 254 can be modulated to improve the performance of sensor system 240. For example, intensity, spectrum, phase and polarization of the emission from the light source 254 can be modulated.

In specific example of implementation, light source 254 can be modulated to prevent saturation of sensor system 240 while keeping a high signal to noise ratio (SNR). A feedback mechanism between the light source 254 and light detection system can be used to increase the current to light source 254 until a threshold value is met. For example, the current to light source 254 can be increased until it is close to the saturation of light sensitive elements 228. In an example, if the threshold is surpassed, the feedback mechanism decreases the current to light source 254. In an example using this example, a maximum SNR can be obtained and maintained during operation. In another example, the feedback mechanism can be used to increase current to light source 254 until sensor system 240 determines that the SNR meets a minimum threshold, enough allowing sensor system 240 to reduce current to light source 254 to save power.

In another specific example of implementation, light source 254 can be modulated to differentiate between a signal produced by light source 254 and ambient light. In an example, the modulation can be used to reduce the impact of ambient light. In a specific example, a feedback mechanism transmits the parameters of the light source 254 to sensor system 240 during modulation of light source 254 and in an example, substantially any contribution in the detected signal that does not follow the modulation is determined to be due to ambient light and can thus be removed in postprocessing. In a specific related example, by removing the contribution of ambient light distance spectrometry measurement accuracy can be improved.

Referring again to FIG. 20, in an example a light source, such as light source 254, will have relatively well known and controlled emission parameters. In an example, the emission parameters can be one or more of spectrum, intensity, phase and polarization. In an example, the known and controlled emission parameters can be used in combination with a spectral system, such as sensor system 240, to obtain spectral information from a region of interest, such as a scene or object or a portion thereof.

In another example, a light source, such as light source 254, with known and controlled emission parameters can be used to calibrate a spectral sensor, such as sensor system 240. In yet another specific example, the combination of a light source, such as light source 254, and a spectral sensor, such as the spectral sensor of sensor system 240 can be used to authenticate a measurement. In an example, the emission parameters of a known light source would be expected to match parameters detected by the spectral system. In an example, the “known” parameters could be used, for example, to confirm that the light source is illuminating the same region of interest that the spectral sensor is detecting.

Referring again to FIG. 20, a light source can be paired with the light detection system as part of a feedback mechanism for calibrating and/or controlling both light detection and as part of a feedback mechanism for calibrating and/or controlling one or more light sources. In an example, calibration can be an essential element for providing reliable spectral measurements from a spectral module and/or spectral sensing system. In an example, calibration can be executed during manufacturing by comparing the response of a spectral module to one or more known illumination sources and compensating for any measured differences. In another example, factors such as aging of a light sensor or light source and temperature drifting, among others, can affect the performance of a spectral module. For example, illumination properties, as well as a sensor's spectral response can change according to post manufacturing processes, temperature changes and other variations encountered in the use of the sensor. In an example, a calibration step can include a closed-loop process to measure sensor system attributes and correct for undesired system performance. In a specific example, a reflectance methodology can be utilized, such that light from a known target is reflected and measured as a reference.

FIGS. 25B and 25C provide a side-view of a sensor system combining a light detection system and a light source for calibration with a bi-modal shutter. In an example, one or more dedicated illumination sources (light source 254) and one or more light sensing arrays (light sensitive elements 228) are provided in a sensor system package. In the example, a controllable transmissive/reflective mechanism (shutter)—316A and 316B in FIGS. 25B and 25C, such as a liquid crystal shutter or a mechanical shutter is included, where the shutter is adapted to either open, as in 316B, allowing light to enter the package, or close, as in 316B, effectively blocking light from entering the package. In an example illustrated in FIG. 25B the light source 254 is adapted to illuminate when the shutter is closed (316A), such that light from light source 254 can be reflected by the shutter to illuminate the one or more light sensing arrays. In a related example, the shutter is configured to provide a reflective surface for reflecting light back to the light sensing array. In the example of FIG. 25C the shutter is open (316B), allowing incoming incident light to be detected by the one or more light sensitive elements 228. In a related example, light source 254 can be further adapted to illuminate a scene when the shutter is open.

In a specific example of implementation and operation, the shutter is a liquid crystal shutter adapted to block light when a voltage is applied. In an example, the liquid crystal shutter comprises a liquid crystal display that includes a single large pixel that covers the package opening, where the shutter is “open” in a clear state, or “closed”, in an opaque state. In an example, the display can be toggled between its open and closed state by applying, for example, a square wave drive voltage. In an alternate example, the shutter comprises a mechanical mechanism with, for example, movable blades or leaves adapted to control the length of time that incoming incident light passes through the package opening.

Referring to FIG. 25B, in an example, when the shutter is in reflective mode light is reflected from the illumination source to the light sensing array to provide a reference for calibration. Referring to FIG. 25C, in an example, when the shutter is in transmissive mode the illumination source can illuminate a scene and, at the same time, allow input light from the scene to reach the light sensing array. In an example, the incoming incident light is sensed and can then be compared with the reference to obtain a corrected and/or calibrated spectrum of the scene.

In a specific example of implementation, an illumination source and a sensor module can be included in a sensor system package, where the sensor system package includes the controllable transmissive/reflective mechanism (shutter). In an alternative example, a sensor module includes one or more illumination source and one or more light sensing elements along with one or more shutters. In yet another specific example, a blocking surface or gate is disposed between the illumination source and light sensing elements in the sensor module. In an alternative example, the illumination source and light sensing elements are disposed without a blocking surface or gate. In some embodiments, the system of FIGS. 25B and 25C can be adapted for use in mobile devices. Examples of mobile devices include, but are not limited to, smart mobile phones, smart watches, calibration devices, medical equipment, fitness devices and crowd-sourced monitoring devices.

FIG. 25D provides a logic diagram of a method for calibrating a spectral sensor. The method begins at step 500 with a controllable transmissive/reflective mechanism (shutter) set to a reflective (closed) mode and continues at step 502, with one or more light sensing elements sampling light that has reflected from the shutter to create a calibration reference. In an example, the shutter has a respective top and a respective bottom surface, where the top surface is adapted to face a scene or object and the bottom surface is adapted to face one or more illumination sources and one or more light sensing elements. In a specific example, the shutter bottom surface is adapted to at least partially reflect light emitted by the illumination source. In another example, the one or more illumination sources and the light sensing elements are located in a container, with the shutter adapted to substantially control light entering the container. At step 504 the shutter is set to a transmissive (open) mode and at step 506 the illumination source is used to illuminate a scene or object. In an alternative step, the scene or object is illuminated with a natural and/or external illumination source and in yet another example, the scene or object is illuminated with a natural and/or external illumination source in addition to the illumination source. The method then continues at step 508, with the light sensing elements sampling incident light from the scene or object to create a measured output and then continues at step 510, with the measured output being compared to the calibration reference to create a spectral image of the scene or object.

FIG. 25E provides a logic diagram of another method for calibrating a spectral sensor. The method begins at step 520 with a controllable transmissive/reflective mechanism (shutter) set to a reflective (closed) mode and continues at step 522, with one or more light sensing elements sampling light that has reflected from the shutter to create a calibration reference. In an example, the shutter has a respective top and a respective bottom surface, where the top surface is adapted to face a scene or object and the bottom surface is adapted to face one or more illumination sources and one or more light sensing elements. In a specific example, the shutter bottom surface is adapted to at least partially reflect light emitted by the illumination source. In another example, the one or more illumination sources and the light sensing elements are located in a container, with the shutter adapted to substantially control light entering the container. At step 524 the shutter is set to a transmissive (open) mode and at step 528 the illumination source is used to illuminate a scene or object. In an alternative step, the scene or object is illuminated with a natural and/or external illumination source and in yet another example, the scene or object is illuminated with a natural and/or external illumination source in addition to the illumination source. The method then continues at step 530, with the light sensing elements sampling incident light from the scene or object to create a measured output. The method continues at step 532 by determining whether a desired or minimum number of samples have been received and when a desired or minimum number of samples have not been received the method returns to step 520 to repeat steps 520 to 530. When a desired or minimum number of samples have been received, the method continues at step 534, with the measured output being compared to the calibration reference to create a spectral image of the scene or object. In an alternative example, step 534 can proceed directly from step 530 before a determination is made at step 532 whether a minimum or desired number of sample have been received; in the alternative example, in an additional step (not shown) a final spectral image of the scene or object is created.

In an example, successive comparison of the measured output can be compared to one or more calibration references in a “tuning” process to create a spectral image of the scene or object. By successively obtaining calibration references and measurements with different illumination source spectra more information, such as the presence of other light sources, can be obtained for a scene or object.

FIGS. 25F and 25G provide a side-view of another sensor system combining a light detection system and a light source for calibration with a bi-modal shutter. In the example, the spectral module, such as the spectral module describe with reference to FIG. 25B is used as a calibration module that is part of a sensor system 320 that includes one or more additional light sensing elements (such as light sensitive elements 228). In an example, the light sensitive elements 228 and integrated spectral filters 222 for the calibration module are fabricated with the additional light sensitive elements in a same process. In an example, fabricating the calibration and measurements elements in the same process can reduce variability in the fabrication process. In an example, utilizing a portion of the sensors to a calibration function can allow the transmissive/reflective mechanism (shutter) (316A and 316B) to be less complicated and/or expensive, which can reduce the cost of the shutter. In the example illustrated in FIG. 25F, one or more light sources 254 are adapted to illuminate when the shutter is closed (316A), such that light from a light source 254 can be reflected by the shutter to illuminate the one or more light sensing arrays comprised of light sensitive elements 228 and thereby used for calibration. In the example, the additional light sensitive elements 228 can sample light from a scene or object even when the shutter is closed for calibration. In the example of FIG. 25G the shutter is open, allowing incoming incident light to be detected by the one or more light sensing arrays comprised of light sensitive elements 228 used for calibration and the additional comprised of light sensitive elements 228.

As discussed with reference to FIGS. 19A and 19B, interference-based filters, such as Fabry-Perot filters, can be sensitive to the angle-of-incidence of incoming light. The angle-of-incidence of a light passing through an interference-based can define the spectral transmission of the interference-based filters. In an example, changing the angle of incidence can result in a change to the center wavelength and the width of the transmitted spectrum changes. In an example, a variation in center wavelength due to a change or difference in angle of incidence can be used to analyze the spectrum of incoming light.

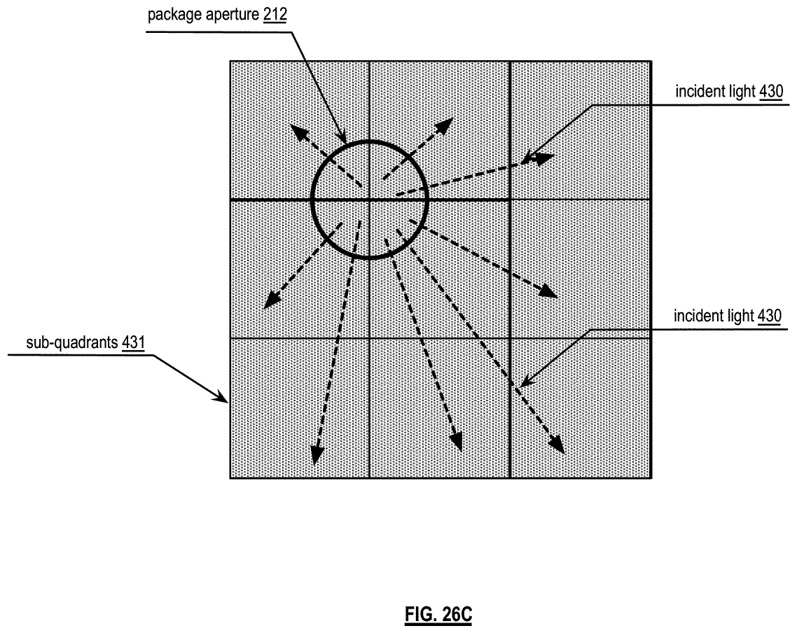

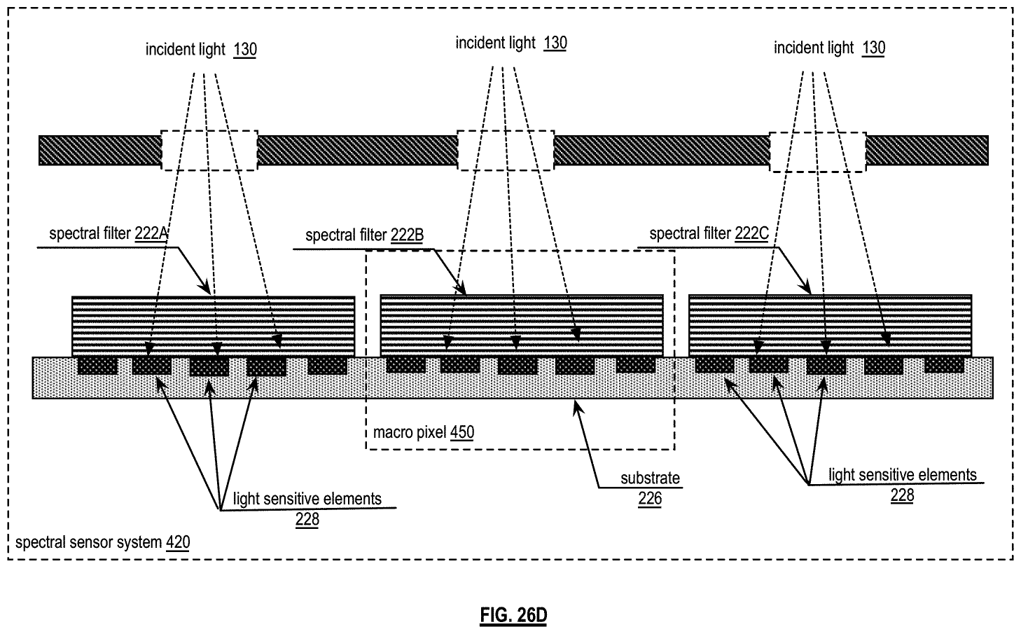

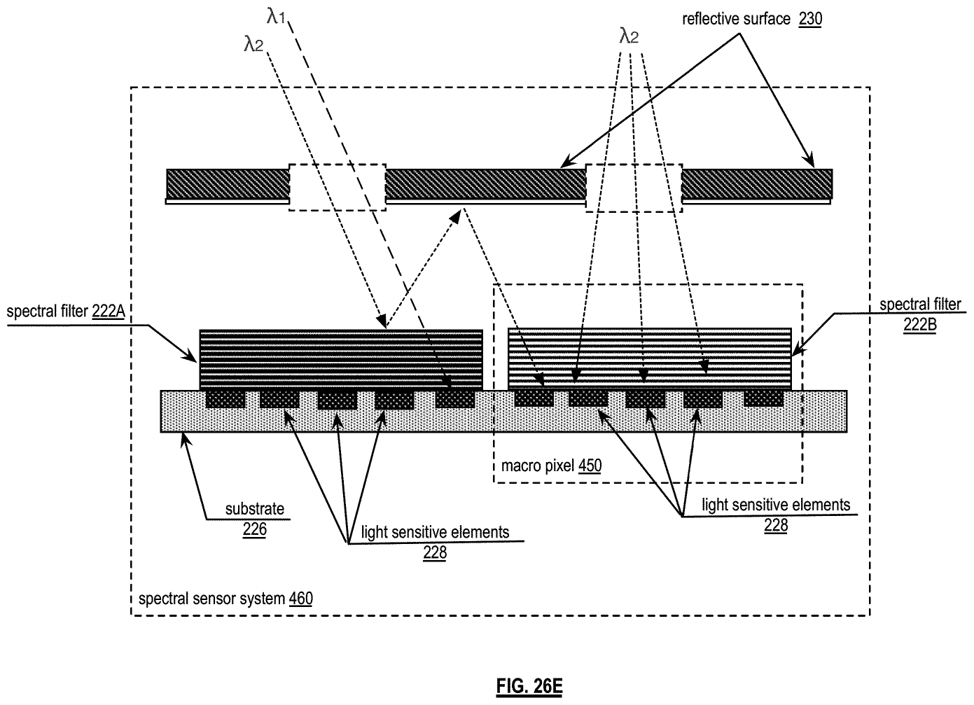

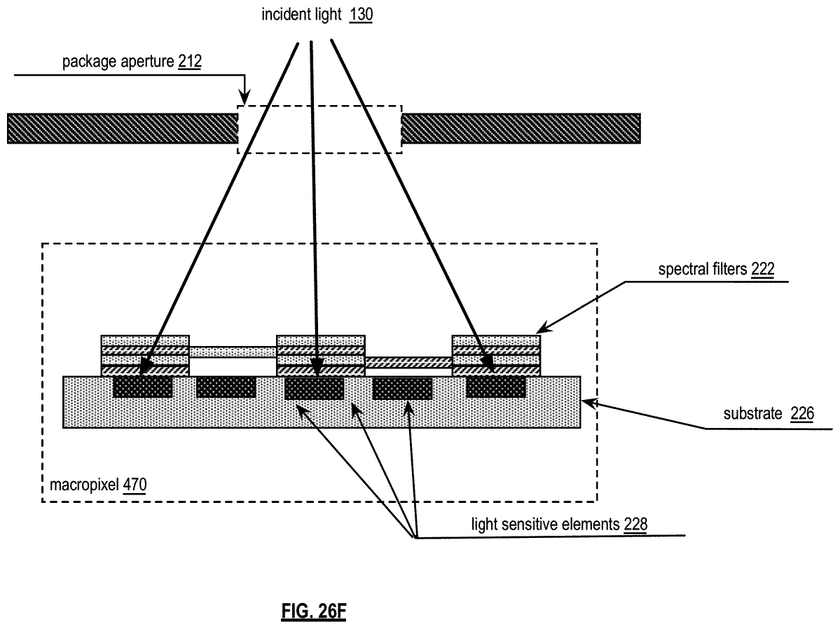

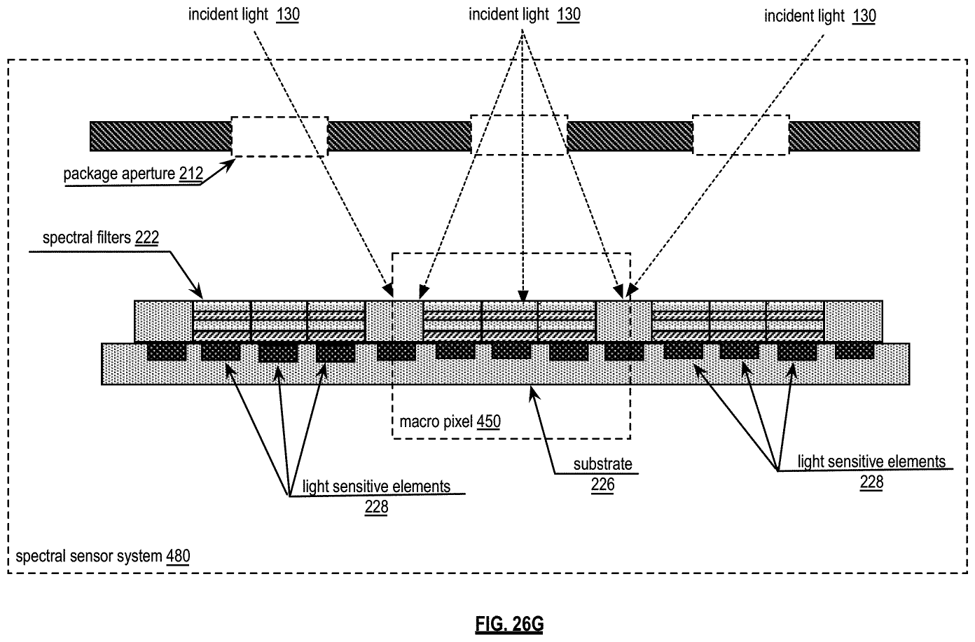

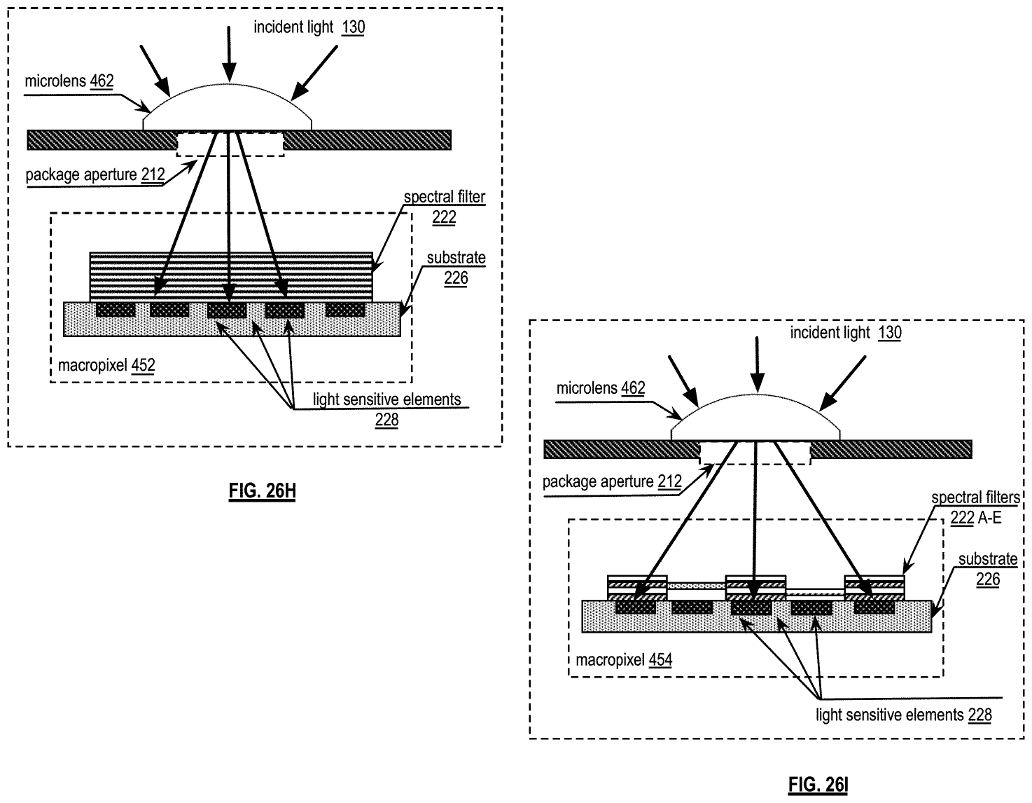

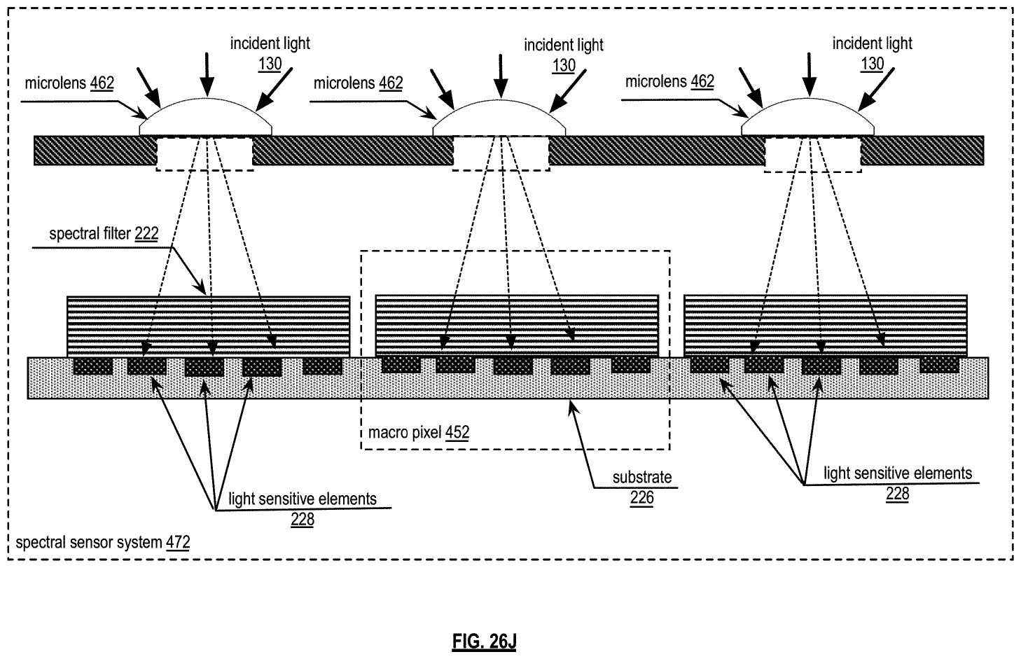

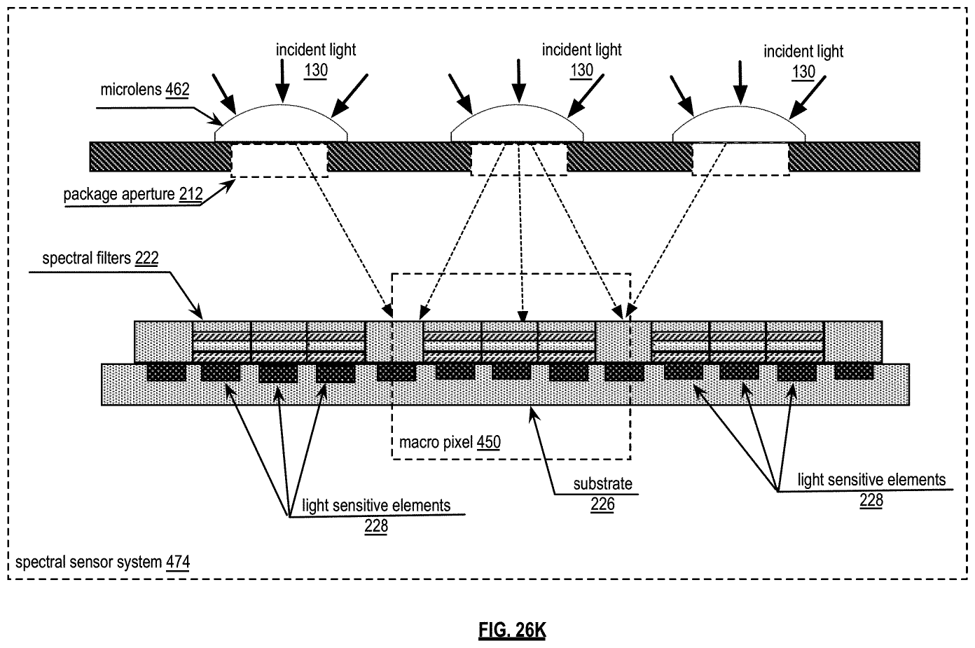

FIG. 26A provides a side-view of a spectrometer system illustrating changes to measured center wavelengths based on the angle of incidence of incoming incident light 130. In the example, a group or set of light sensitive elements 228 are located under a single interference-based filter (spectral filter 222) to form a macro-pixel 400. In the example, the group of light sensitive elements 228 are configured as a layer having a respective top surface and a respective bottom surface, with the single spectral filter 222 having a respective top surface and a respective bottom surface, the bottom surface of the spectral filter 222 being proximate to the top surface of the top surface of the group of light sensitive elements 228. In an example, a single aperture (package aperture 212) having a respective top surface and a respective bottom surface is positioned above the single interference-based filter. In an example, the size of the single aperture and its position relative to the individual light sensitive elements in the group of light sensitive elements defines an angle of incidence of incoming light to the individual light sensitive elements. In an example, the angle of incidence of incoming light defines the transmitted spectrum of the single interference-based filter in the direction of each light sensitive element, accordingly, each light sensitive element of the group of light sensing elements can measure a different spectral profile with respect to other light sensing elements of the group of light sensing elements comprising a macro-pixel.

In a specific example, an output from different light sensing elements of a group of light sensing elements comprising a macro-pixel can be used to measure different spectral responses, where the different spectral responses are due at least in part to different center wavelengths of light reaching the different light sensing elements. In an example, the spectral responses resulting from the varying center wavelengths of light can result in a slightly modified measured spectrum.

In a specific example of implementation and operation, a sensor module includes a substrate having a respective bottom surface and a respective top surface, with one or more sets of light sensitive elements located on the top surface of the substrate. The sensor module further includes one or more interference filters configured as a layer having a respective top surface and a respective bottom surface, where the bottom surface of the one or interference filters is located atop the one or more sets of light sensitive elements and where each interference filter of the one or more interference filters is configured to pass light in a predetermined wavelength range. Each interference filter of the one or interference filters is associated with a set of the one or more sets of light sensitive elements. The sensor module further includes one or more apertures, each having a respective top surface and a respective bottom surface, where the bottom surface of each aperture is located above an interference filter of the one or more interference filters. In a specific related example, each of the one or more apertures has a respective width and depth, the width and depth of the aperture together defining an angle-of-incidence of light received at the top surface of the one or more interference filters. In another specific related example, the location of each light sensitive element of the set of light sensitive elements can be adapted to provide increased spectral resolution for the sensor module based on the angle of incidence of light received at each interference filter of the one or more interference filters.

FIG. 26B provides a side-view of another spectrometer system illustrating changes to measured center wavelengths based on the angle of incidence of incoming light. In an example, an aperture, such as package aperture 212 described in reference to FIG. 26A, is offset relative to the center of a macro-pixel. In an example, the offset aperture extends the range of angles for the angle of incidence of incident light 130 received at the light sensitive elements 228 of the group of light sensitive elements 228 comprising the macro-pixel. FIG. 26C provides a top-down view of an offset aperture with respect to the center of a macro-pixel. In an example, locating the aperture closer to a corner of a macro-pixel comprising a group of light sensitive elements can provide a relatively broader distribution of angles-of incidence of incident light 430 for the group of light sensing elements, which can be used to provide relatively more broad spectral spread for the measure spectrum, such as across 9 sub-quadrants 431 of the macro-pixel.

FIG. 26D provides a side-view of a spectral sensor system 420 illustrating macro-pixel(s) 450 associated with interference-based filters (spectral filters 222A-222C) and apertures. In an example, groups of light sensing elements comprising macro-pixel(s) 450 in a spectrometer system are associated with a spectral filter 222A, 222B or 222C, where each of the spectral filters 222A-222C manifests a different transmission profile, and with each of 222A, 222B and 222C having an associated aperture for collection of incident light 130.

In a specific example of implementation and operation, a sensor module includes a substrate having a respective bottom surface and a respective top surface, with a plurality of sets of light sensitive elements located on the top surface of the substrate. The sensor module further includes a plurality of interference filters configured as a layer having a respective top surface and a respective bottom surface, where the bottom surface of the plurality of interference filters located atop the one or more sets of light sensitive elements and where each interference filter of the plurality of interference filters is configured to pass light in a predetermined wavelength range. Each interference filter of the plurality of interference filters is associated with a set of the plurality of light sensitive elements. The sensor module further includes a plurality of apertures, each having a respective top surface and a respective bottom surface, where the bottom surface of each aperture of the plurality of apertures is located above an interference filter of the plurality of interference filters. In a specific related example, each aperture of the plurality of apertures has a respective width and depth, the width and depth of the aperture together defining an angle-of-incidence of light received at the top surface of the one or more interference filters. In another specific related example, at least some interference filters of the plurality of interference filters is configured to pass light in a different wavelength range. In yet another specific related example, the width and depth of at least some apertures of the plurality of apertures is configured to provide different ranges for angles-of-incidence of incoming light.

In a specific related implementation example, different apertures of the plurality of apertures can be separated by and/or associated with opaque regions, with a reflective layer deposited on the bottom surface of the aperture in the opaque regions. In an example, light reflected at the top surface of an interference filter of the plurality of interference filters can be subsequently reflected at the bottom surface of the opaque regions until it reaches an interference-based filter with the desired parameters for transmission. In an example, each interference filter of the plurality of interference filters is separated from adjacent interference filters with an airgap. In an alternative example, each interference filter of the plurality of interference filters is contiguous with one or more adjacent interference filters.

FIG. 26E provides a side-view of the example spectrometer system of 26D illustrating light propagation with reflective apertures. In the example, two incoming light rays with different central wavelengths λ1 and λ2 pass through the left aperture. In the example, spectral filter 222A is designed to transmit light with wavelength λ1 and reject other wavelengths; as a result, light with wavelength λ2 is rejected. In an example, by including reflective surface 230 on the opaque bottom surface between the plurality of apertures, rejected light is reflected until it reaches spectral filter 222B that allows wavelength λ2 to transmit through.

FIG. 26F provides a side-view of another spectrometer system illustrating macro-pixels associated with interference-based filters and apertures. In the example, a plurality of spectral filters 222 are associated with a single macro-pixel 470 and a package aperture 212. In an example, the angle of incidence of incident light 130 passing through package aperture 212 can be compensated for by incorporating one of spectral filters 222 with predetermined transmission characteristics. In a specific example of implementation and operation, a sensor module includes a substrate 226 having a respective bottom surface and a respective top surface, with a plurality of sets of light sensitive elements 228 located on the top surface of the substrate 226. The sensor module further includes a plurality of sets of spectral filters 222 configured as a layer having a respective top surface and a respective bottom surface, where the bottom surface of the plurality of sets of spectral filters 222 is located atop the one or more sets of light sensitive elements 228 and where each spectral filter 222 of the plurality of spectral filters 222 is configured to pass light in a predetermined wavelength range. In an example, each spectral filter 222 of a set of spectral filters 222 is associated with a set of light sensitive elements 228. The sensor module further includes a plurality of package apertures 212, each having a respective top surface and a respective bottom surface, where the bottom surface of each package aperture 212 of the plurality of package apertures 212 is located above a set of spectral filters 222. In an example, the predetermined transmission characteristics for at least some of the spectral filters 222 are determined based on angles of incidence for light passing through a package aperture 212 associated with those spectral filters 222 and a micropixel 470. In the example, the predetermined transmission characteristics for the spectral filters 222 are further determined to compensate for select angles of incidence of light passing through the associated package aperture 212.

FIG. 26G provides a side-view of another spectrometer system illustrating macro-pixels associated with interference-based filters and apertures. In the example, each of a plurality of macro-pixels 450 and its corresponding package aperture 212 are located adjacent to each other and provide a macro-pixel 450 and package aperture 212 pair. In an example, spectral filters 222 (such as interference-based filters) associated with a macro-pixel 450 and package aperture 212 pair are arranged so that light sensitive elements 228 in a group of light sensitive elements 228 comprising a macro-pixel 450 can receive light with angles of incidence sufficient to cross more than one package aperture 212 with substantially a same angle of incidence. In a specific example, light of sufficient angles of incidence passing through adjacent package apertures 212 can overlap at a spectral filter 222 common to adjacent macro-pixels 450.

In an example, angle selecting elements can be structured to provide various types of control for light passing through an aperture. Example structures can be found in FIGS. 12A-12F of U.S. patent application Ser. No. 17/007,254, which is incorporated herein by reference in its entirety.

FIGS. 26H and 26I provide side-views of a spectrometer system illustrating the use of a lens to control the angle of incidence received at a macro-pixel. In the example of FIG. 26H, a package aperture 212, having a respective top surface and a respective bottom surface, includes a lens (micro-lens 462) having a respective top surface and a respective bottom surface located with the bottom surface of the micro-lens 462 directly atop the top surface of package aperture 212, with the bottom surface of the aperture facing one or more macro-pixels. In an example, the top surface of micro-lens 462 is adapted to narrow an angle of incidence of incoming incident light 130 on a single spectral filter 222 of macro-pixel 452. In the example of FIG. 26I, the top surface of micro-lens 462 is adapted to narrow an angle of incidence of incoming incident light on a set of spectral filters 222 associated with macro-pixel 452.

In the example, one or more lenses can be used to redirect incident light rays coming from wide angles in the direction normal to the surface of an image sensor incorporating macro-pixels, creating a substantially collimated beam. In a specific example of implementation and operation, referring to FIG. 1, a package 16 having a respective top surface, a respective bottom surface and a respective plurality of side surfaces with the top surface includes a package aperture 12, the top surface, the plurality of side surfaces and the bottom surface forming a cavity. In an example, one or more lenses are configured atop the package aperture 12, where the one or more lenses are adapted to redirect incoming incident light in a direction substantially perpendicular to the top surface of package 16.

In an example, a substrate 26 having a respective bottom surface and a respective top surface is located within the cavity of package 16, the bottom surface of the substrate 26 being coupled to the bottom surface of the package 16 and one or more sets of light sensitive elements 28 are located on the top surface of the substrate 26. In the example, a plurality of sets of interference filters having a respective top surface and a respective bottom surface are located atop the plurality of light sensitive elements 28.

FIG. 26J provides a side-view of a spectrometer system illustrating the use micro-lenses to control the angle of incidence received at a macro-pixel. In an example, a plurality of macro-pixels 452 are associated with a plurality of package apertures 212 to create macro-pixel 452 and package aperture 212 pairs, where an array of micro-lenses 462 is configured such that each micro-lens 462 of the array is associated with a package aperture 212 of a macro-pixel 452 and package aperture 212 pair.

FIG. 26K provides a side-view of another spectrometer system illustrating the use micro-lenses to control the angle of incidence received at a macro-pixel. In an example, a plurality of macro-pixels 450 are associated with a plurality of package apertures 212 to create a plurality of macro-pixel 450 and package apertures 212 pairs. In the example, each package aperture 212 is further associated with a micro-lens 462, such that the angle of incidence of light passing through the package aperture 212 includes angles of incidence sufficient to pass to adjacent macro-pixel 450 and package aperture 212 pairs. In an example, individual light sensitive elements 228 at a boundary of a group of light sensitive elements 228 comprising a macro-pixel 450 can receive light crossing from an adjacent macro-pixel 450 and package aperture 212 pair. In an example, light with a substantially same angle of incidence can be detected by light sensitive elements 228 at the boundary of two adjacent macro-pixels 450.

It is noted that terminologies as may be used herein such as bit stream, stream, signal sequence, etc. (or their equivalents) have been used interchangeably to describe digital information whose content corresponds to any of a number of desired types (e.g., data, video, speech, text, graphics, audio, etc. any of which may generally be referred to as ‘data’).

As may be used herein, the terms “substantially” and “approximately” provide industry-accepted tolerance for its corresponding term and/or relativity between items. For some industries, an industry-accepted tolerance is less than one percent and, for other industries, the industry-accepted tolerance is 10 percent or more. Other examples of industry-accepted tolerance range from less than one percent to fifty percent. Industry-accepted tolerances correspond to, but are not limited to, component values, integrated circuit process variations, temperature variations, rise and fall times, thermal noise, dimensions, signaling errors, dropped packets, temperatures, pressures, material compositions, and/or performance metrics. Within an industry, tolerance variances of accepted tolerances may be more or less than a percentage level (e.g., dimension tolerance of less than +/−1%). Some relativity between items may range from a difference of less than a percentage level to a few percent. Other relativity between items may range from a difference of a few percent to magnitude of differences.

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processing module”, “processing circuit”, “processor”, “processing circuitry”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, processing circuitry, and/or processing unit may be, or further include, memory and/or an integrated memory element, which may be a single memory device, a plurality of memory devices, and/or embedded circuitry of another processing module, module, processing circuit, processing circuitry, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, processing circuitry, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, processing circuitry and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, processing circuitry and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with one or more other routines. In addition, a flow diagram may include an “end” and/or “continue” indication. The “end” and/or “continue” indications reflect that the steps presented can end as described and shown or optionally be incorporated in or otherwise used in conjunction with one or more other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid-state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A sensor system comprises:
a plurality of sets of optical sensors configured in a layer, the plurality of sets of optical sensors having a respective top surface and a respective bottom surface;
a plurality of sets of optical filters configured in a layer having a respective top surface and a respective bottom surface, wherein the bottom surface of the plurality of sets of optical filters is located proximal to the top surface of the plurality of sets of optical sensors, wherein a set of optical filters of the plurality of sets of optical filters includes a plurality of optical filters that are arranged in a pattern, wherein some optical filters of the plurality of optical filters are configured to pass light in a different wavelength range;
one or more rejection filters configured as a layer having a respective top surface and a respective bottom surface;
a first set of optical elements having a respective top surface and a respective bottom surface; wherein the one or more rejection filters and the first set of optical elements are configured in a stack, wherein the stack is located above the top layer of the plurality of sets of optical filters; and
one or more processing modules, wherein the one or more processing modules are configured to receive an output from each optical sensor of the plurality of sets of optical sensors, wherein the one or more processing modules are further configured to generate a spectral response based on the output.

2. The sensor system of claim 1, further comprising one or more diffusion elements having a respective top surface and a respective bottom surface, wherein the one or more rejection filters and the first set of optical elements are configured in a stack with the one or more diffusion elements, wherein the stack is located above the top layer of the plurality of sets of optical filters.

3. The sensor system of claim 1, wherein the sensor system further comprises a second set of optical elements having a respective top surface and a respective bottom surface, wherein the bottom surface of the second set of optical elements is located atop the first set of optical elements.

4. The sensor system of claim 1, wherein the plurality of optical filters comprises interference filters.

5. The sensor system of claim 1, wherein each rejection filter of the one or more rejection filters is adapted to restrict light wavelengths outside a predetermined wavelength range through the rejection filter.

6. The sensor system of claim 1, wherein an optical element of the first set of optical elements is selected from a group comprising: an aperture stop, a lens, a dispersive element, a fiber optic plate, a pinhole, a microlens, a micro-grating, a nanoscale lens and a plurality of baffles, wherein each baffle of the plurality of baffles extends incident to the respective bottom surface of the first set of optical element.

7. The sensor system of claim 3, wherein at least one optical element of the second set of optical elements is selected from a group comprising: a pinhole, a lens, an aperture stop, a diaphragm, a meta-lens, a planar lens, a dispersive element, and a lens stack.

8. The sensor system of claim 1, further comprising:
a container having a respective top surface, a respective bottom surface and a respective plurality of side surfaces with the top surface including a container opening, wherein the top surface, the plurality of side surfaces and the bottom surface form a cavity; wherein at least the plurality of sets of optical sensors, the plurality of sets of optical filters and the first set optical elements are located within the cavity.

9. The sensor system of claim 8; wherein the bottom surface of the plurality of sets of optical sensors is located proximate to the bottom surface of the container.

10. The sensor system of claim 8, wherein the bottom surface of the one or more processing modules is located proximate to the bottom surface of the container.

11. The sensor system of claim 8, wherein a substantially transparent material is at least partially located within the container opening.

12. The sensor system of claim 8, further comprising:
one or more diffusion elements, wherein at least one of the one or more rejection filters, one or more diffusion elements and one or more optical elements of a second set of optical elements is partially located within the container opening.

13. The sensor system of claim 8, wherein at least a portion of the respective top surface, the plurality of side surfaces and the bottom surface of the container are adapted to reflect light entering the cavity.

14. The sensor system of claim 8, further comprising:
a container having a respective bottom surface and a respective plurality of side surfaces forming a container opening, wherein the top surface, the plurality of side surfaces and the bottom surface form a cavity; wherein at least the plurality of sets of optical sensors, the plurality of sets of optical filters and the first set of optical elements are located within the cavity.

15. A method for manufacturing an optical sensor system, the method comprising:
forming an array of optical sensors on an integrated circuit, the array of optical sensors having a respective top surface;
forming a plurality of optical filters having a respective top surface and a respective bottom surface, wherein the bottom surface of the plurality of optical filters is located proximal to the top surface of the array of optical sensors;
forming a rejection filter having a respective top surface and a respective bottom surface;
forming a first set of optical elements having a respective top surface and a respective bottom surface;
configuring the rejection filter and the first set of optical elements in a stack having a respective top surface and a respective bottom surface; and
placing the bottom surface of the stack atop the top surface of the plurality of sets of optical filters.
coupling the array of optical sensors to one or more processing modules, wherein the one or more processing modules are configured on a substrate having a respective top surface and a respective bottom surface, wherein the substrate is configured to provide one or more electrical connections.

16. The method of claim 15, further comprising:
forming a diffusion element having a respective top surface and a respective bottom surface;
configuring the rejection filter, the first set of optical elements and the diffusion element in a stack having a respective top surface and a respective bottom surface; and
placing the bottom surface of the stack atop the top surface of the plurality of sets of optical filters.

17. The method of claim 15, further comprising:
forming a second set of optical elements having a respective top surface and a respective bottom surface; and
placing the bottom surface of the second set of optical elements atop the top surface of the stack.

18. The method of claim 15, wherein the rejection filter comprises a plurality of rejection filter elements.

19. The method of claim 16, wherein the diffusion element comprises a plurality of diffusion sub-elements.

20. The method of claim 15, further comprising:
forming a container having a respective top surface, a respective bottom surface and a respective plurality of side surfaces, wherein the plurality of side surfaces and the bottom surface of the container form a cavity, wherein the top surface includes an opening, to the cavity; and
placing the integrated circuit and the plurality of optical filters within the cavity.

21. The method of claim 20, further comprising:
placing the bottom surface of the substrate to the bottom surface of the container.

22. The method of claim 20, further comprising:
forming a reflective surface on at least a portion of the top surface, the plurality of side surfaces and the bottom surface, wherein the reflective surface is adapted to reflect light entering the cavity.

23. The method of claim 20, wherein the optical filters are interference filters.

24. The method of claim 20, wherein the optical filters are Fabry-Perot filters.

25. The method of claim 20, wherein the array of optical sensors is formed on a backside of the integrated circuit.
